(19) United States
(12) Patent Application Publication
(10) Pub. No.: US 2026/0223494 A1
(43) Pub. Date: Jul. 30, 2026

(54) REFLECTIVE MIRROR LAYER FOR MICRO-LED AND METHOD FOR FORMING THE SAME, PHOTORESIST RING, AND MICRO-LED CHIP

(71) Applicant: Hue Inc., Shanghai (CN)

(72) Inventor: Feng Feng, Shanghai (CN)

(73) Assignee: Hue Inc., Shanghai (CN)

(21) Appl. No.: 19/458,874

(22) Filed: Jan. 25, 2026

(30) Foreign Application Priority Data
Jan. 26, 2025 (CN) 202510124080.X

(51) Int. Cl. H10H 20/841; H10H 20/01; H10H 20/814; H10H 29/01; H10H 29/80; H10H 29/856

(52) U.S. Cl. CPC H10H 20/841; H10H 20/034; H10H 20/0363; H10H 20/814; H10H 29/034; H10H 29/0363; H10H 29/8421; H10H 29/856

(57) ABSTRACT

The present disclosure relates to a reflective mirror layer for a micro-LED, and the reflective mirror layer is configured to reflect light from the light-emitting mesa toward the light extraction side, and the area of the upper surface of the light-emitting mesa facing the light extraction side is greater than the area of the lower surface facing away from the light extraction side, wherein the reflective mirror layer includes: a main body portion arranged to cover the lower surface of the light-emitting mesa and surround the side surface of the light-emitting mesa; and an edge portion connected with the edge of the main body portion and forming an angle greater than 0° with the main body portion, wherein the edge portions of the reflective mirror layers of adjacent micro-LEDs are disconnected from each other. The present disclosure also relates to a method for manufacturing the reflective mirror layer.

### CROSS-REFERENCE TO RELATED APPLICATION

This application claims the priority benefit of China application serial no. 202510124080.X, filed on January 26, 2025. The entirety of the above-mentioned patent application is hereby incorporated by reference herein and made a part of this specification.

### BACKGROUND

### Technical Field

The present disclosure generally relates to the field of micro-LEDs, and more specifically relates to a reflective mirror layer for a micro-LED and a method for forming the same, photoresist ring and micro-LED chip. Furthermore, the present disclosure also relates to a micro-LED having such a reflective mirror layer.

### Description of Related Art

Micro light-emitting diode (Micro-LED) is a new type LED structure obtained by thin-filming, miniaturizing, and arraying the original LED structure, which integrates the arrayed micro level micro-LEDs on an active addressing drive panel to achieve the lighting and individual control of the micro-LEDs, thereby outputting the desired display image. The core structure of the micro-LED is a light-emitting mesa, which includes a PN junction diode, and the PN junction diode is composed of direct-bandgap semiconductor material. When the upper and lower electrodes apply a forward bias voltage to the micro-LED to allow current to pass through, electrons and holes recombine in the active area, and meanwhile emit monochromatic light photons.

The reflective mirror layer is a reflective structure surrounding the light-emitting mesa, and its function is to reflect the light emitted by the light-emitting mesa towards the direction of the microlens. Currently, the reflective mirror layer is generally manufactured through processes such as photolithography, etching, deposition, etc. However, the current reflective mirror layer is limited by the process, and the reflective mirror layer is prone to defects such as small coverage area or incomplete coverage, and difficulty in removing photoresist molded bodies, etc.

### SUMMARY

The task of the present disclosure is to provide a reflective mirror layer for a micro-LED and a method for forming the same, The method for forming the reflective mirror layer provided by the present disclosure can reduce the defects of the reflective mirror layer, thereby improving the luminous efficiency of the micro light-emitting diode.

In a first aspect of the present disclosure, the aforementioned task is solved by a reflective mirror layer for a micro-LED, and the reflective mirror layer is configured to reflect light from the light-emitting mesa toward the light extraction side, an area of an upper surface of the light-emitting mesa facing the light extraction side is greater than an area of a lower surface facing away from the light extraction side, where the reflective mirror layer comprises:

a main body portion configured to cover a lower surface of the light-emitting mesa and surround a side surface of the light-emitting mesa; and

an edge portion configured to connect with an edge of the main body portion and have an angle greater than 0° with the main body portion, where the edge portions of the reflective mirror layers of adjacent micro-LEDs are disconnected from each other.

In one embodiment of the present disclosure, the range of the angle is 5° to 85°.

In another embodiment of the present disclosure, it is provided that:

a length of the edge portion ranges from 0.1 μm to 0.2 μm, and a thickness of the edge portion ranges from 0.2 to 0.4 μm; and/or

a thickness of the main body portion ranges from 0.2 μm to 0.5 μm; and/or

a lowermost side of the edge portion is flush with or not flush with the lower surface of the light-emitting mesa.

In another embodiment of the present disclosure, the cross-sectional shape of the main body portion in a cross-section parallel to the upper surface of the light-emitting mesa is one of the following:

a triangle, a square, a rectangle, a circle, an ellipse, or polygon with n sides, where n is an integer greater than 4.

In another embodiment of the present disclosure, the cross-sectional shape of the main body portion is square, and the cross-sectional shape of the light-emitting mesa is circle, where the circle is an inscribed circle of the square and the circle has rounded outer corners.

In another embodiment of the present disclosure, it is provided that:

a lowest side of a connection portion provided between the edge portion and the main body portion has a distance of 0 to 0.8 μm from the upper surface of the light-emitting mesa; and/or

a distance between the edge portions of the reflective mirror layers of adjacent micro-LEDs ranges from 0.3 μm to 2 μm.

In another embodiment of the present disclosure, the reflective mirror layer includes, starting from a side facing the light-emitting mesa:

an atomic layer deposition layer, the material of the atomic layer deposition layer is selected from a group including the following items: nickel, platinum, titanium, and tantalum;

a reflective metal layer configured to reflect light, the material of the reflective metal layer is selected from a group including the following items: silver, aluminum, and gold;

a first barrier layer comprising at least a first barrier sublayer and a second barrier sublayer, where the materials of the first barrier sublayer and the second barrier sublayer are respectively selected from a group comprising the following items: platinum, titanium, and tantalum; and

a second barrier layer, the material of the second barrier layer is selected from a group including the following items: platinum, titanium, and tantalum.

In another embodiment of the present disclosure, the material of the second barrier layer is the same as the material of the first barrier sublayer.

In another embodiment of the present disclosure, it is provided that:

the material of the atomic layer deposition layer is nickel;

the material of the reflective metal layer is silver;

the materials of the first barrier sublayer and the second barrier sublayer are titanium and platinum, respectively; and

the material of the second barrier layer is titanium.

In another embodiment of the present disclosure, it is provided that:

a thickness of the atomic layer deposition layer ranges from 3 angstroms to 8 angstroms;

a thickness of the reflective metal layer ranges from 800 angstroms to 1200 angstroms;

a thickness of the first barrier sublayer ranges from 100 angstroms to 300 angstroms, and the thickness of the second barrier sublayer ranges from 400 angstroms to 600 angstroms; and

a thickness of the second barrier layer ranges from 100 angstroms to 300 angstroms.

In another embodiment of the present disclosure, the reflective mirror layer includes N first barrier sublayers and N second barrier sublayers arranged alternately with each other, where N is an integer and N=2 to 5.

In a second aspect of the present disclosure, the aforementioned task is solved by a photoresist ring for forming the reflective mirror layer according to the present disclosure, where the photoresist ring is configured to form (e.g., mold) the reflective mirror layer, and the photoresist ring includes:

a lower layer ring surrounding the light-emitting mesa of the micro-LED; and

an upper layer ring located on the lower layer ring, where at a connection portion between the upper layer ring and the lower layer ring, a thickness of the upper layer ring is greater than a thickness of the lower layer ring.

In one embodiment of the present disclosure, at the connection portion between the upper layer ring and the lower layer ring, the thickness of the upper layer ring is greater than the thickness of the lower layer ring by 20% to 60%.

In another embodiment of the present disclosure, the height of the lower layer ring is 2/3 of a height of the light-emitting mesa; or

the height of the lower layer ring is the same as a height of the light-emitting layer of the light-emitting mesa.

In another embodiment of the present disclosure, it is provided that:

the height of the lower layer ring ranges from 0.2 μm to 0.5 μm, and a height of the upper layer ring ranges from 1.3 μm to 1.7 μm; and/or

the thickness of the lower layer ring ranges from 1.9 μm to 2.4 μm, and the thickness of the upper layer ring ranges from 1.8 μm to 2.3 μm.

In another embodiment of the present disclosure, the bottom of the upper layer ring is lower than the lower surface of the light-emitting mesa, and the top is higher than the lower surface of the light-emitting mesa.

In another embodiment of the present disclosure, it is provided that:

the cross-sectional shape of the upper layer ring and/or the lower layer ring in a cross-section parallel to the upper surface of the light-emitting mesa is one of the following items: a triangle, a square, a rectangle, a circle, an ellipse, and an n-sided polygon, where n is an integer greater than 4; and/or

the longitudinal cross-sectional shape of the upper layer ring and/or the lower layer ring in a longitudinal cross-section perpendicular to the upper surface of the light-emitting mesa is one of the following items: a trapezoid, a triangle.

In another embodiment of the present disclosure, the cross-sectional shape of the upper layer ring and the lower layer ring is square, and the square has rounded inner angles.

In another embodiment of the present disclosure, the lower layer ring is formed in a first photolithography step, and the upper layer ring is formed in a second photolithography step after the first lithography step.

In another embodiment of the present disclosure, it is provided that:

the lower layer ring has a gradually decreasing thickness in the longitudinal cross-section perpendicular to the upper surface of the light-emitting mesa; and

the upper layer ring has a gradually decreasing thickness in the longitudinal cross-section perpendicular to the upper surface of the light-emitting mesa.

In a third aspect of the present disclosure, the aforementioned task is solved by a micro-LED chip, and the micro-LED chip includes:

a light-emitting mesa, including:

a transparent conductive layer arranged on a side of the light-emitting mesa facing away from the light extraction side;

a light-emitting layer;

a first epitaxial layer located between the transparent conductive layer and the light-emitting layer; and

a second epitaxial layer located on a side of the light-emitting mesa facing the light extraction side, where the light-emitting layer is located between the first epitaxial layer and the second epitaxial layer, and an area of the second epitaxial layer is larger than an area of the first epitaxial layer;

a reflective mirror layer according to claim 1, surrounding the light-emitting mesa;

an insulating layer accommodating the light-emitting mesa and a plurality of through-hole contact portions;

a drive circuit comprising a metal layer on its surface, the drive circuit is provided with the plurality of through-hole contact portions, and the plurality of through-hole contact portions are electrically connected with the metal layer, and a micro-LED array area is bonded onto the drive circuit through a bottom conductive bonding layer, where the drive circuit also comprises a wiring stacked layer below the metal layer;

a first electrode electrically connected with the plurality of through-hole contact portions, where the wiring stacked layer leads out the first electrode;

a passivation layer covering at least a part of a side surface of the light-emitting mesa;

a top transparent conductive layer located on a surface of the passivation layer and in electrical contact with the second epitaxial layer; and

a second electrode located on a surface of the transparent conductive layer.

In one embodiment of the present disclosure, the second electrode is a circular reflective electrode arranged around the light-emitting mesa.

In another embodiment of the present disclosure, the polarity of the second electrode is opposite to the polarity of the first electrode.

In another embodiment of the present disclosure, the material of the second epitaxial layer is a material layer of a second conductivity type including two or more elements of Ga, N, As, Al, In, and P, and the first epitaxial layer is a material layer of a first conductivity type including two or more elements of Ga, N, As, Al, In, and P, where the first conductivity type is different from the second conductivity type.

In another embodiment of the present disclosure, the light-emitting layer includes a multi-quantum-well layer, where the multi-quantum-well layer is an InGaN/GaN multi-quantum-well layer, an InGaN/AlGaN multi-quantum-well layer, an InGaAs/AlGaAs multi-quantum-well layer, or an AlGaInP multi-quantum-well layer.

In another embodiment of the present disclosure, an electron blocking layer is arranged on a first side of the light-emitting layer, and the first side is a side along which electrons migrate out of the light-emitting layer.

In another embodiment of the present disclosure, the material of the passivation layer is a Si₃N₄ film, a SiO₂ film, or an Al₂O₃ film.

In another embodiment of the present disclosure, it is provided that:

the material of the insulating layer is selected from the group that includes the following items: silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof; and/or

the material of the metal layer is selected from the group that includes the following items: aluminum (Al), copper (Cu), tungsten (W), silver (Ag), gold (Au), nickel (Ni), platinum (Pt), tantalum (Ta), and molybdenum (Mo).

In another embodiment of the present disclosure, the through-hole contact portions include a first and a second through-hole contact portions, and the insulating layers include a first and a second insulating layers, and the micro-LED chip includes an upper stacked layer and a lower stacked layer, where the upper stacked layer includes the first insulating layer, the light-emitting mesa, and the first through-hole contact portion, and the lower stacked layer includes the second insulating layer, the second through-hole contact portion, and the drive circuit, where the lower stacked layer is jointed with the upper stacked layer through hybrid bonding, such that the first through-hole contact portion is bonded with the second through-hole contact portion, and the first insulating layer is bonded with the second insulating layer.

In a fourth aspect of the present disclosure, the aforementioned task is solved by a method for forming a reflective mirror layer, the method includes the following steps:

providing a light-emitting mesa;

forming a lower layer ring around the light-emitting mesa;

forming an upper layer ring on the lower layer ring, where at the connection portion between the upper layer ring and the lower layer ring, a thickness of the upper layer ring is greater than the thickness of the lower layer ring;

coating a reflective mirror layer on the light-emitting mesa, the upper layer ring, and the lower layer ring, where the reflective mirror layer forms, at the connection portion, an overhang layer detached from the lower layer ring, and the lower layer ring has a gap under the overhang layer that is not covered by the reflective mirror layer; and

removing the upper layer ring and the lower layer ring.

In one embodiment of the present disclosure, forming the lower layer ring around the light-emitting mesa and forming the upper layer ring on the lower layer ring includes the following steps:

covering the light-emitting mesa with photoresist to form a first photoresist layer;

exposing the first photoresist layer;

covering the first photoresist layer with photoresist to form a second photoresist layer;

exposing the second photoresist layer; and

developing and rinsing the first and second photoresist layers to form the lower layer ring and the upper layer ring.

In another embodiment of the present disclosure, removing the upper layer ring and the lower layer ring includes:

cleaning the upper layer ring and the lower layer ring with a stripping solution such that the stripping solution enters the bottom of the lower layer ring through the gap;

removing the lower layer ring through the stripping solution; and

removing the upper layer ring connected the lower layer ring by removing the lower layer ring.

The present disclosure has at least the following beneficial effects:

(1) In the present disclosure, by using a photoresist ring to form the reflective mirror layer, the quality of the reflective mirror layer is improved, this is because the photoresist ring can reliably isolate and disconnect the reflective mirror layers of adjacent light-emitting mesas to prevent short circuits, meanwhile, the photoresist ring can confine the formed reflective mirror layer within the desired range, i.e. surrounding the light-emitting mesa, meanwhile, it can also ensure that the metal is sufficiently deposited onto the lower surface and side surface of the light-emitting mesa. Manufactured in this manner, the reflective mirror layer can be reliably isolated between adjacent light-emitting mesas, meanwhile, an edge portion inclined or curved towards the lower surface of the light-emitting mesa can be formed at its edge, so that the edge of the reflective mirror layer is far away from the conductive structure on the upper surface of the light-emitting mesa, such as the epitaxial layer or transparent conductive layer, to prevent short circuits, meanwhile, it can also ensure that the reflective mirror layer has sufficient thickness on the upper surface of the light-emitting mesa, sufficient coverage at the edge is ensured and the quality of edge coverage is improved.

(2) The photoresist ring used in the present disclosure is a dual-layer structure with an upper layer ring and a lower layer ring, where the connection between the upper layer ring and the lower layer ring has a thickness jump, therefore, when coating a reflective mirror layer on the light-emitting mesa, the upper layer ring, and the lower layer ring, the reflective mirror layer forms an overhang layer detached from the lower layer ring at the connection, and since the reflective mirror layer cannot continue to adhere to the overhang layer, the lower layer ring has a gap under the overhang layer that is not covered by the reflective mirror layer. The gap can permit the stripping solution to enter the root of the lower layer ring during the stripping process, so that the lower layer ring is reliably removed through the stripping solution, and meanwhile, the upper layer ring on the lower layer ring and the reflective mirror layer attached to it are removed, therefore, complete removal of the photoresist molded body is achieved.

(3) By changing the shape of the photoresist ring, the shape of the reflective mirror layer can also be reliably changed. For example, by using a square photoresist ring, a square reflective mirror layer surrounding the light-emitting mesa can be formed, thereby increasing the reflective surface. Using the photoresist ring, reflective mirror layers of other shapes, such as triangles, rectangles, ellipses, circles, and n-sided polygons with n greater than four can be achieved.

(4) By adding an atomic layer deposition layer made of a barrier metal on the side of the reflective mirror layer facing the light-emitting mesa, therefore, the metal in the reflective mirror layer can be effectively prevented from diffusing into the light-emitting mesa through the bottom transparent conductive layer arranged between the reflective mirror layer and the light-emitting mesa, causing performance degradation or failure of the light-emitting mesa, and it suppresses the oxidation of the reflective metal, thereby suppressing the decrease in reflection efficiency caused by oxidation. Furthermore, in the present disclosure, the metal barrier effect is significantly improved by changing the number of alternating metal layers (e.g., alternating layers of platinum and titanium) in the reflective mirror layer; furthermore, second and third barrier layers made of barrier metals are also arranged on the side of the reflective mirror layer facing away from the light-emitting mesa, diffusion of easily diffusible metals such as silver from the reflective mirror layer into the insulating layer is effectively suppressed, so that short circuits or failures of the insulating layer caused by diffusion are avoided.

### BRIEF DESCRIPTION OF THE DRAWINGS

The present disclosure is further explained below with reference to the accompanying drawings in conjunction with specific implementation methods.

FIG. 1 illustrates a first embodiment of a reflective mirror layer for a micro-LED according to the present disclosure.

FIG. 2 illustrates a second embodiment of a reflective mirror layer for a micro-LED according to the present disclosure.

FIG. 3 illustrates a first embodiment of a layered structure of the reflective mirror layer according to the present disclosure.

FIG. 4 illustrates a second embodiment of a layered structure of the reflective mirror layer according to the present disclosure.

FIG. 5 illustrates a first application scenario of the reflective mirror layer according to the present disclosure.

FIG. 6 illustrates a schematic diagram of a first embodiment of a photoresist ring for forming the reflective mirror layer according to the present disclosure.

FIG. 7 illustrates a schematic diagram of a second embodiment of a photoresist ring for forming the reflective mirror layer according to the present disclosure.

FIG. 8 illustrates a top view schematic diagram for forming the reflective mirror layer according to the present disclosure.

FIGS. 9A to 9D illustrate the steps of a method for forming the reflective mirror layer.

### DESCRIPTION OF THE EMBODIMENTS

It should be noted that various components in the accompanying drawings may be exaggerated for the purpose of illustrative illustration and are not necessarily true to scale. In the accompanying drawings, components that are identical or functionally identical are provided with the same accompanying drawing reference signs.

In the present disclosure, unless otherwise specified, the words "arranged on", "arranged above" and "arranged over" do not exclude the existence of intermediates between the two. Furthermore, "arranged on or above" merely indicates the relative positional relationship between the two components, but under certain circumstances, such as when the product direction is reversed, it can be converted to "arranged under or below", and vice versa.

In the present disclosure, the embodiments are merely intended to illustrate the scheme of the present disclosure and should not be construed as limiting.

In the present disclosure, the quantifiers "a" and "one" do not exclude scenarios with a plurality of elements, unless otherwise specified.

In the present disclosure, the term "connect" may refer to either the two being directly connected or the two being indirectly connected through an intermediate component

In the present disclosure, the term "configure" refers to the setting of the shape, structure, material, and/or function of a target object to achieve a desired technical effect, where "configure" includes various alternative technical means to achieve this technical effect, these technical means become apparent under the teachings of the present disclosure.

It should also be noted herein that in embodiments of the present disclosure, merely a part of the components or assemblies may be shown for the sake of clarity and simplicity, but those ordinary skilled in the art will be able to understand that the required components or assemblies may be added as needed according to specific scenarios in light of the teachings of the present disclosure. Furthermore, features in different embodiments of the present disclosure may be combined with each other unless otherwise indicated. For example, a feature in the second embodiment may be substituted for a corresponding or functionally identical or similar feature in the first embodiment, and the obtained embodiment likewise falls within the scope of the disclosure or the scope of the record of the present application.

It should also be noted that, within the scope of the present disclosure, the terms "the same", "equal", "equal to", etc. do not mean that the two numerical values are absolutely equal, but rather allow for a certain reasonable error, that is to say, the terms also cover "substantially the same ", "substantially equal " and "substantially equal to". By analogy, in the present disclosure, the terms "perpendicular to", "parallel to", etc., which indicate direction, also cover the meaning of "substantially perpendicular to", "substantially parallel to".

In the present disclosure, the term "configure" refers to the setting of the shape, structure, material, and/or function of a target object to achieve a desired technical effect, where "configure" includes various alternative technical means to achieve this technical effect, these technical means become apparent under the teachings of the present disclosure.

In the present disclosure, the term "upward reflect" refers to light being reflected such that the distance between the reflected light and the upper surface of the light-emitting mesa increases. The upward direction includes directly above and diagonally above.

In the present disclosure, the term "upper surface of the light-emitting mesa" refers to the surface of the light-emitting mesa facing the light extraction side (i.e., the lens direction), while the term "lower surface of the light-emitting mesa" refers to the surface of the light-emitting mesa facing away from the light extraction side (e.g., toward the drive circuit). The term "side surface of the light-emitting mesa" refers to the surface of the light-emitting mesa located between the upper surface and the lower surface of the light-emitting mesa.

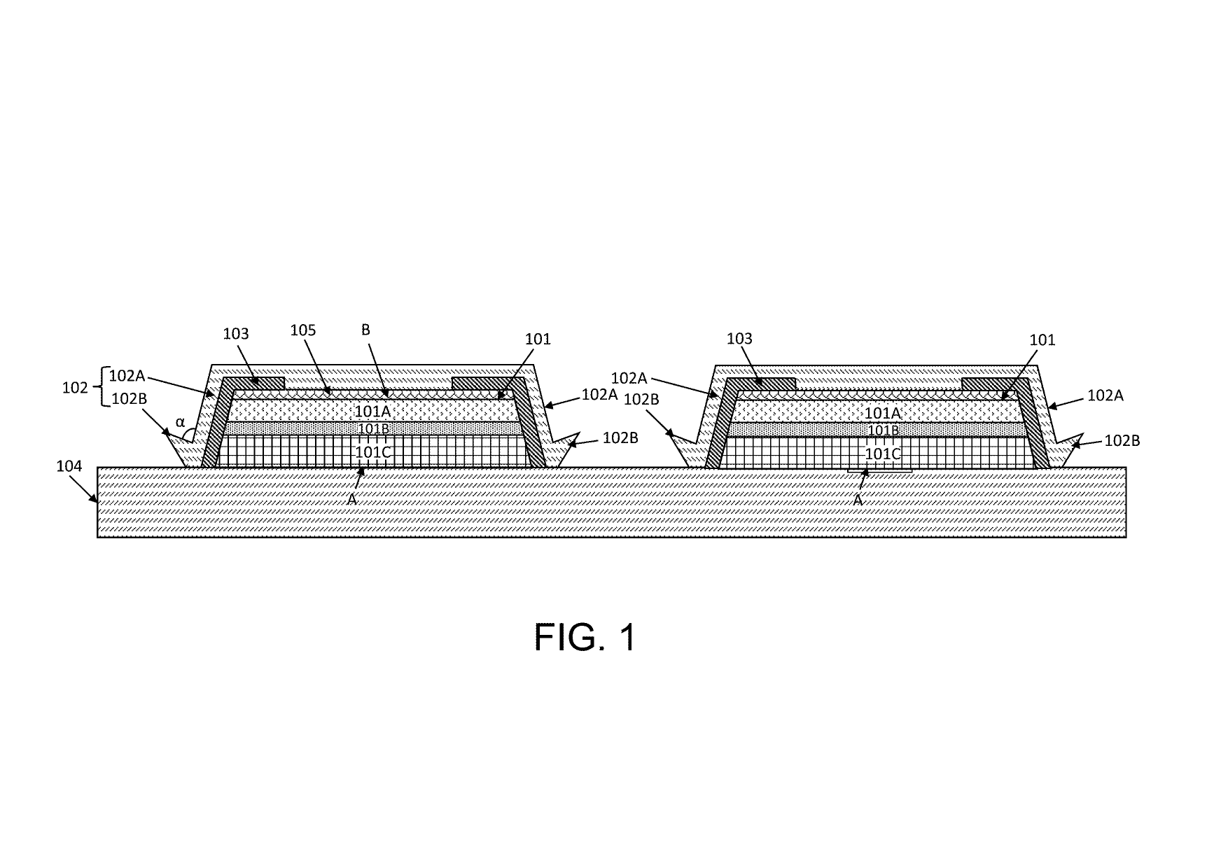

FIG. 1 illustrates a first embodiment of the reflective mirror layer 102 for a micro-LED according to the present disclosure.

As shown in FIG. 1, the reflective mirror layer 102 for a micro-LED according to the present disclosure is configured to reflect light from the light-emitting mesa 101 of the micro-LED toward the light extraction side (direction A in the figure). The area of the upper surface A of the light-emitting mesa 101 facing the light extraction side is larger than the area of the lower surface B facing away from the light extraction side.

The light-emitting mesa 101 is configured to emit light, and includes a first epitaxial layer 101C, a light-emitting layer 101B, and a second epitaxial layer 101A, where the first epitaxial layer 101C has a different conductivity type from the second epitaxial layer 101A, such as one being n-type and the other being p-type, or vice versa. The light-emitting mesa 101 is arranged on a temporary substrate 104. After the temporary substrate 104 is removed (e.g., through debonding or grinding), the upper surface of the light-emitting mesa 101 will be exposed. A transparent conductive layer 105 is arranged at the lower surface B of the light-emitting mesa 101, and is configured to electrically connect the second epitaxial layer 101A at the lower surface B to an electrode (not shown, e.g., an anode) through a conductive reflective mirror layer 102. Furthermore, a passivation layer 103 is arranged on the side surface and a part of the bottom surface B of the light-emitting mesa 101, and the passivation layer 103 is configured to reduce current leakage, passivate side wall defects at the side walls, and block damage to the light-emitting mesa 101 caused by water, oxygen, etc. during operation. The passivation layer 103 has a notch on the lower surface B to expose the transparent conductive layer 105 for electrical connection. The inclination angle between the side surface of the light-emitting mesa 101 located between the upper surface A and lower surface B, and the upper surface B may be 55° to 75°, preferably 60° to 70°, to improve the aperture ratio.

The reflective mirror layer 102 includes a main body portion 102A and an edge portion 102B. These two portions are described below, respectively.

### Main body portion

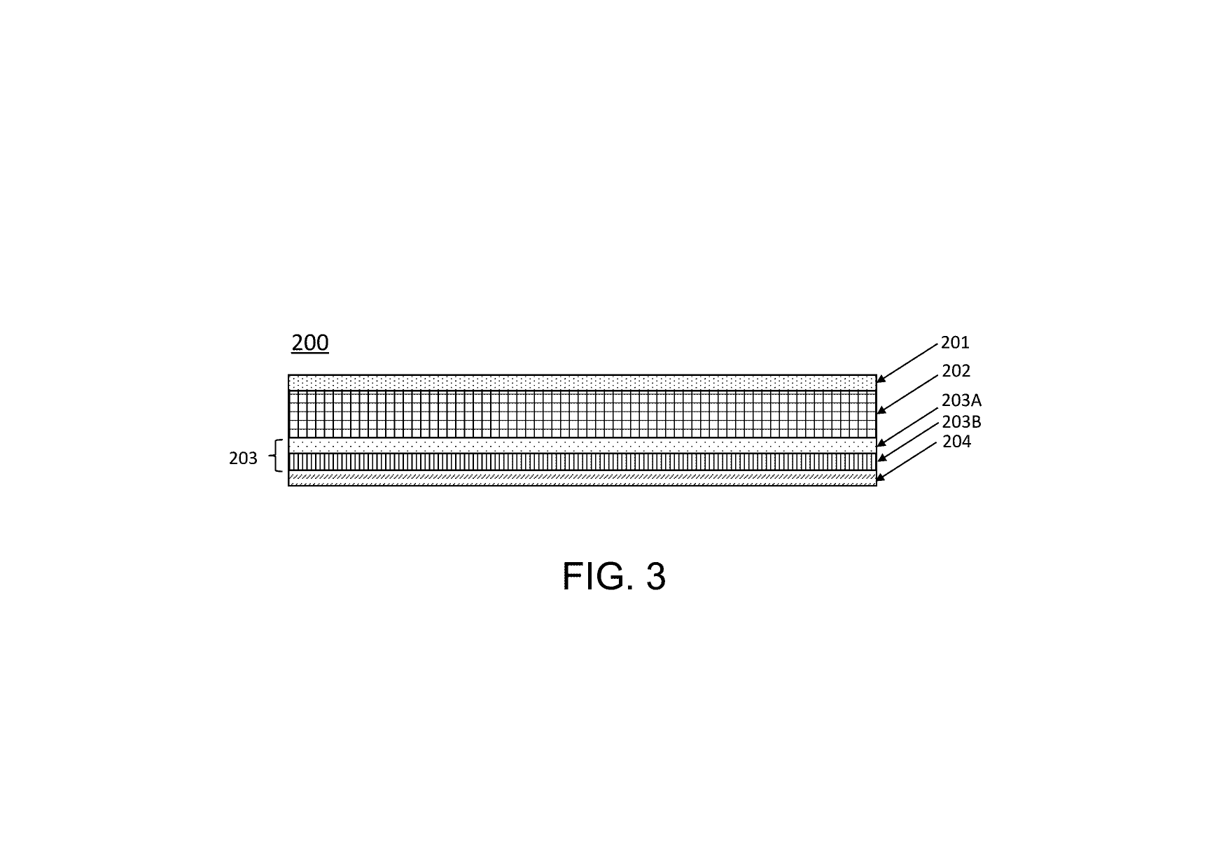

The main body portion 102A is arranged to cover the lower surface B of the light-emitting mesa 101 and surround the side surface between the upper surface A and lower surface B of the light-emitting mesa 101. Herein, the main body portion 102A of the reflective mirror layer 102 fills the notch of the passivation layer 103 for electrical connection between the transparent conductive layer 105 and the electrode. In the present embodiment, the reflective mirror layer 102 covers the entire side surface of the light-emitting mesa 101, however, in other embodiments, the reflective mirror layer 102 may also cover merely a part of the side surface of the light-emitting mesa 101. The side surface portion of the main body portion may have the same inclination angle with the upper surface of the light-emitting mesa 101 as that between the side surface and upper surface A of the light-emitting mesa 101, this inclination angle is, for example, 55° to 75°, preferably 60° to 70°. The side surface portion and bottom surface portion of the main body portion 102A substantially completely cover the surface of the light-emitting mesa 101 except for the upper surface A used for light emission, and both portions can reflect the light emitted from the light-emitting mesa 101 toward the light extraction side, i.e., the direction of the upper surface A, therefore, as much light as possible of the light-emitting mesa 101, which is oriented outside the light extraction side, is reflected, this light can be redirected to the light extraction side after one or more reflections, thereby improving the light output rate or light extraction efficiency (LEE) of the micro-LED. The thickness of the main body portion can be, for example, 0.2 to 0.5 μm. For the layered structure and materials of the main body portion 102A and the edge portion 102B, reference may be made to FIG. 3 and its description.

### Edge portion

The edge portion 102B of the reflective mirror layer 102 is connected with the edge or end of the main body portion 102A of the reflective mirror layer 102, and an angle α greater than 0° is formed between the edge portion 102B and the main body portion 102A, where the edge portions 102B of the reflective mirror layers 102 of adjacent micro-LEDs are disconnected from each other. The length of the edge portion 102B may be, for example, 0.1 to 0.2 μm, and the thickness may be, for example, 0.2 to 0.4 μm. According to different processes or different shape of the photoresist ring used to form the edge portion 102B, the angle α may be 5° to 85°, preferably 20° to 70°, most preferably 30° to 60°, for example 45°. The lowermost side of the edge portion 102B may be flush with or not flush with the lower surface B of the light-emitting mesa 101, i.e., on a straight line or not on a straight line (higher than the lower surface B). For example, the distance between the lowest side of the connection portion between the edge portion and the main body portion, and the upper surface of the light-emitting mesa is 0, i.e., they are in contact, or this distance is not 0, i.e., they are not in contact, and the distance may be, for example, 0 to 0.8 μm. The longitudinal cross-sectional shape of the edge portion 102B in a longitudinal cross-section perpendicular to the upper surface may be, for example, a triangle, a rectangle, a trapezoid, an ellipse, an irregular shape with a curved surface, etc. The edge portions 102B of the reflective mirror layer 102 of adjacent micro-LEDs are disconnected from each other without electrical contact, and the distance between them may be, for example, 0.3 to 5 μm. For the layered structure and materials of the main body portion 102A and edge portion 102B, reference may be made to FIG. 3 and its description.

From the above structure, it can be seen that the reflective mirror layer 102 according to the present disclosure has good quality, this is because the reflective mirror layer 102 is disconnected from each other between adjacent light-emitting mesas 101 to prevent short circuits. Meanwhile, there is also an edge portion 102B bent or inclined towards the lower surface B of the light-emitting mesa at the edge of the reflective mirror layer 102, such that the edge of the reflective mirror layer 102 can be away from the conductive structures, such as epitaxial layers or transparent conductive layers, at the upper surface A of the light-emitting mesa 101, thereby reducing the risk of short circuits; meanwhile, it can also ensure that the reflective mirror layer 102 has sufficient thickness at the upper surface A of the light-emitting mesa 101, which ensures sufficient coverage at the edges and improves the quality of edge coverage.

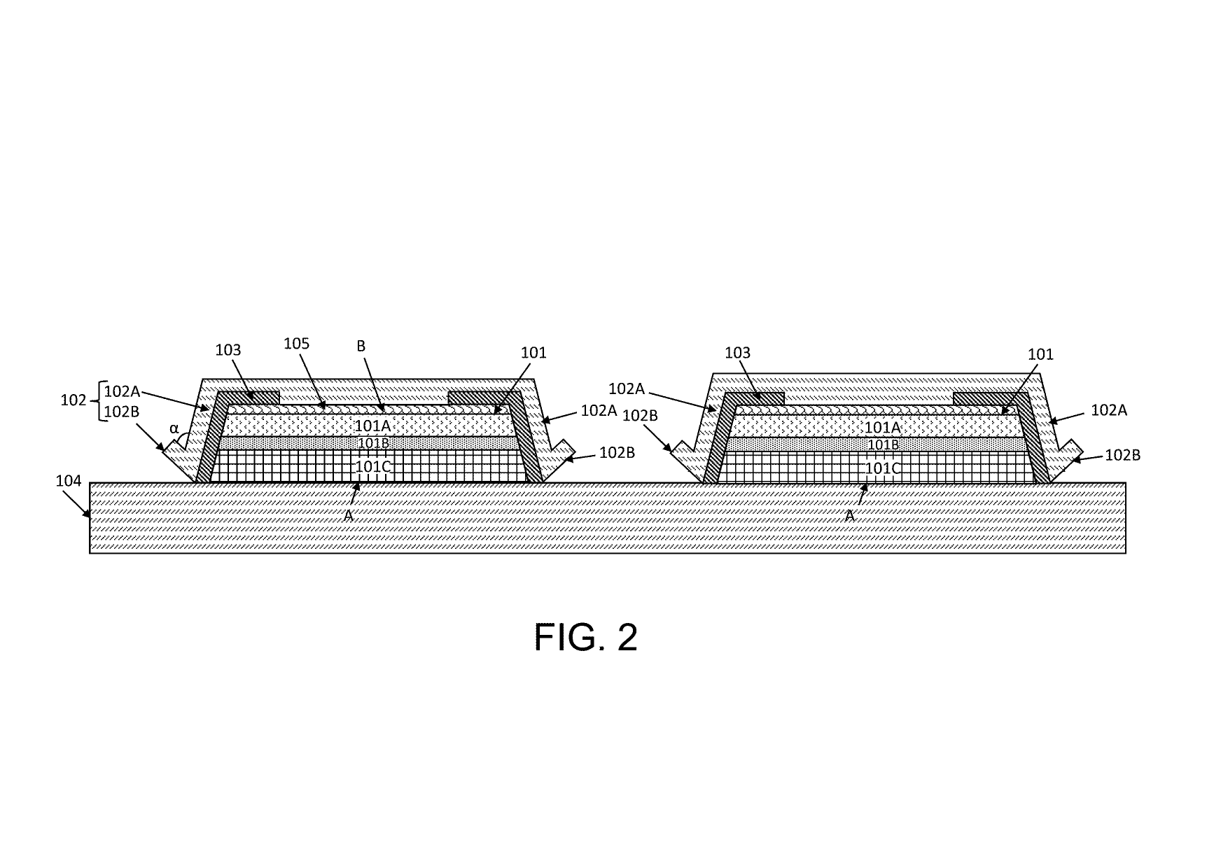

FIG. 2 illustrates a second embodiment of the reflective mirror layer 102 for a micro-LED according to the present disclosure.

The second embodiment shown in FIG. 2 is substantially the same as the first embodiment shown in FIG. 1, and the main difference lies in the fact that, in the second embodiment, the edge portion 102B of the reflective mirror layer 102 has a rectangular shape, and the connection portion between the main body portion 102A and the edge portion 102B does not contact the temporary substrate 104, i.e., there is a certain distance from the upper surface A, so that the area of the reflective mirror layer 102 exposed from the insulation layer surrounding the light-emitting mesa 101 is reduced, and thus the risk of short circuits is reduced.

FIG. 3 illustrates a first embodiment of the layered structure of the reflective mirror layer 200 according to the present disclosure.

As shown in FIG. 3, the reflective mirror layer 200 according to the present disclosure includes, from top to bottom, an atomic layer deposition layer 201, a reflective metal layer 202, a first barrier layer 203, and a second barrier layer 204, and the upper side of the reflective mirror layer 200 faces the light-emitting mesa or epitaxial layer of the micro-LED, and the lower side of the reflective mirror layer 200 faces away from the light-emitting mesa or epitaxial layer of the micro-LED or faces the bottom transparent conductive layer. Each layer is described below, respectively.

The atomic layer deposition layer 201, which is arranged at the uppermost layer, i.e., facing the outermost side of the light-emitting mesa or epitaxial layer. The material of the atomic layer deposition layer 201 may include, for example, nickel, platinum, titanium, and tantalum. The preferred material for atomic layer deposition layer 201 is nickel. The thickness of the atomic layer deposition layer is 3 to 8 angstroms, preferably 5 angstroms. 1 angstrom = 10^(-10) meters. The function of the atomic layer deposition layer 201 is to deposit a barrier metal (e.g., nickel) of a certain thickness on the outer side of the reflective metal layer 202 through an atomic layer deposition (ALD) process, and the barrier metal can effectively block or at least suppress outward diffusion of the reflective metal layer 202, such as preventing its diffusion through the transparent conductive layer into the light-emitting mesa or epitaxial layer arranged thereon.

Reflective metal layer 202, which is arranged between the atomic layer deposition layer 201 and the first barrier layer 203, and which is configured to reflect light, and the materials of the reflective metal layer 202 may include silver, aluminum, and gold.

Aluminum (Al): Aluminum is a commonly used optical reflective material. It has high reflectivity, reaching approximately 80%–90% in the visible light range. Moreover, aluminum has a relatively low cost and is easy to form various shapes of reflective mirrors. Aluminum also has a certain reflective capability in the ultraviolet and infrared regions, but its reflective performance will change with the variation of wavelength.

Silver (Ag): The reflectivity of silver is higher than that of aluminum in the visible light band, reaching over 95%, particularly in the blue and green light bands, its reflective performance is more outstanding. However, silver is easily oxidized, and the reflectivity of oxidized silver will decrease. Furthermore, silver is prone to diffusion. Considering that silver is prone to diffusion and oxidation, the inventor has found that, by arranging an atomic layer deposition layer 201 before the silver layer, the diffusion and oxidation of the reflective metal layer made of silver can be effectively prevented.

Gold (Au): Gold has excellent reflective performance in the infrared band, and its reflectivity can reach over 98% in the infrared region. However, the reflectivity of gold in the visible light band is relatively low, and its color is golden yellow, therefore, gold is mainly used for the light reflection of infrared micro-LEDs.

The material of the reflective metal layer 202 is preferably a high-reflectivity metal, such as silver. The thickness of the reflective metal layer may be, for example, 800 to 1200 angstroms, preferably 1000 angstroms.

The principle of metal reflection of light is as follows: when light is incident on the surface of a metal, free electrons in the metal will perform forced vibration under the action of the electric field of light, and these vibrating electrons will radiate electromagnetic waves with the same frequency as the incident light, which is the source of reflected light.

The penetration depth of light in a metal (also known as the skin depth) is a physical quantity that is related to the properties of the metal material and the frequency of light. It represents the distance that light penetrates when its intensity decays to 1/e (approximately 37%) of the surface intensity. For metals, the depth of light penetration is usually at the nanometer level. That is to say, light can penetrate metal surfaces to a certain depth at the nanometer level (such as 200 nanometers).

In view of this, the atomic layer deposition layer 201 is constructed to be as thin as possible, e.g., not exceeding 10 angstroms, such as 3 to 8 angstroms, preferably 5 angstroms, so that light from the light-emitting mesa can penetrate the atomic layer deposition layer 201 on surface as unobstructed as possible and be reflected by the reflective metal layer 202 with high reflectivity arranged behind it. However, on the other hand, if the atomic layer deposition layer 201 is too thin, it will also affect its metal barrier function, therefore, the inventor uniquely configures its layer thickness to be 3 to 8 angstroms, preferably 5 angstroms, to achieve both good metal barrier and high reflectivity of the reflective metal layer 202.

A first barrier layer 203, which is arranged between the reflective metal layer 202 and the second barrier layer 204, and includes at least a first barrier sublayer 203A and a second barrier sublayer 203B. The first barrier sublayer 203A and the second barrier sublayer 203B may, for example, include platinum, titanium, and tantalum, respectively. The thickness of the first barrier layer is 100 to 300 angstroms, preferably 200 angstroms, and the thickness of the second barrier layer is 400 to 600 angstroms, preferably 500 angstroms. For example, the first barrier layer 203 is preferably made of titanium, while the second barrier layer 203B is preferably made of platinum. Furthermore, the first barrier layer 203 may be repeated, for example, the reflective mirror layer 200 may include a plurality of first barrier layers 203 arranged successively with each other, such as 2, 3, 4, 5, or other numbers of first barrier layers 203. The first barrier layer 203 is configured to provide metal barrier and prevent oxidation of the reflective metal layer 202 from the back, particularly, it can block metal atoms such as silver of the reflective metal layer from entering the insulating layer and affecting its insulation properties. Particularly when the first and second barrier sublayers 203A and 203B are titanium and platinum, respectively, the stacked layer of titanium and platinum has the following technical effects:

(1) The stacked layer of titanium and platinum can effectively prevent the reflective layer material from being oxidized or corroded by chemical substances. In the reflective mirror layer, if the basic reflective material (such as silver) is oxidized, its reflectivity will significantly decrease. Titanium and platinum themselves have high chemical stability, which can prevent oxygen and other chemical substances that may cause deterioration of the reflective layer material from contacting the core material of the reflective layer, such as silver, thereby ensuring the reflective performance remains stable during long-term use.

(2) The stacked layer of titanium and platinum can adjust the optical constants of the reflective layer to better adapt to different reflective metals. Different optical devices have different requirements for the optical parameters of the reflective layer (such as refractive index, extinction coefficient, etc.). Titanium and platinum have specific optical properties in the optical frequency band, by adjusting the thickness and number of layers of the stacked layer, the optical characteristics of the reflective metal layer can be finely tuned to meet the needs of specific optical systems. Particularly when the number of stacked layers is 3, it has good reflection characteristics for the light of the light-emitting mesa of the micro-LED, meanwhile also has good metal blocking and oxidation resistance for the silver reflective metal layer.

The second barrier layer 204, which is arranged on the outermost side of the reflective mirror layer 200 facing the bottom transparent conductive layer. Materials of the second barrier layer 204 may include, for example, platinum, titanium, and tantalum, preferably titanium. The thickness of the second barrier layer may be, for example, 100 to 300 angstroms, preferably 200 angstroms. On one hand, the second barrier layer 204 has functions of metal barrier and anti-oxidation, on another hand, it can prevent the oxidation of the reflective metal layer and block its metal diffusion, on another hand, it can participate in the fine-tuning of the reflective characteristics of the reflective metal layer, for example, it can form a titanium-platinum-titanium fine-tuning stacked layer with the first and second barrier sublayers of the first barrier layer 203, in this case, the material of the second barrier layer 204 is preferably different from the material of the first barrier sublayer, for example, both are titanium.

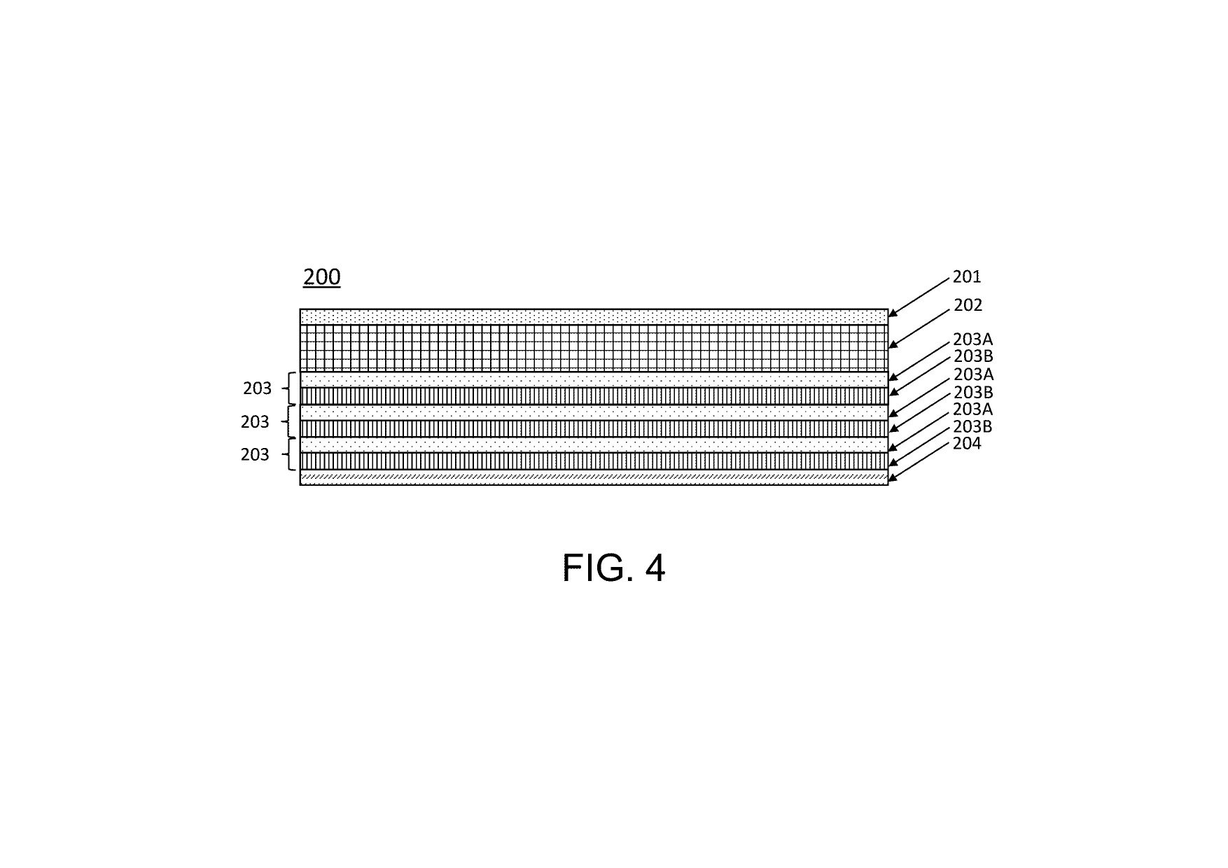

FIG. 4 illustrates a second embodiment of the layered structure of the reflective mirror layer 200 according to the present disclosure.

The reflective mirror layer 200 of the second embodiment is substantially the same as the reflective mirror layer 200 of the first embodiment, and the main difference lies in, in the second embodiment, the material of the atomic layer deposition layer is nickel with a thickness of 5 angstroms, the material of the reflective metal layer is silver with a thickness of 1000 angstroms, the materials of the first and second barrier sublayers are titanium and platinum with thicknesses of 200 and 500 angstroms, respectively, and the material of the second barrier layer is titanium with a thickness of 200 angstroms; furthermore, the number of layers of the first barrier layer 203 is 3.

In the present embodiment, an atomic layer deposition layer 201 made of nickel is arranged on the front side of the reflective metal layer 202, and a first barrier layer 203 composed of three titanium layers and platinum layers is arranged after the reflective metal layer 202 made of silver, so that titanium and platinum alternate with each other, and the second barrier layer 204 made of titanium is arranged after the first barrier layer 203. In this way, the arrangement of three pairs of stacked layers can improve the functions of blocking and oxidation resistance for the silver reflective metal layer, and also fine tune the optical reflection characteristics of silver, furthermore, the second barrier layer and the first barrier layer 203 made of titanium form a titanium-platinum-titanium stacked layer pair, further fine-tuning the reflection characteristics of silver.

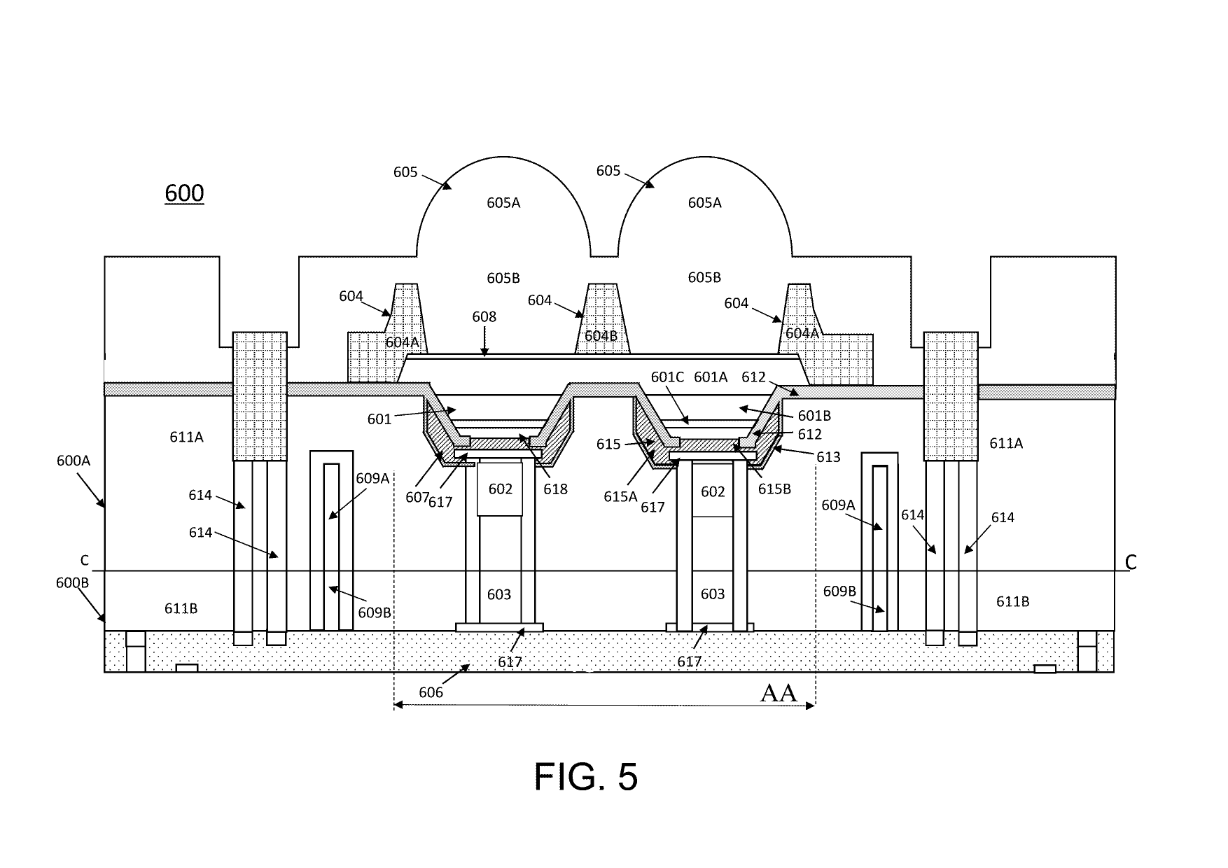

FIG. 5 illustrates a first application scenario of the reflective mirror layer 200 according to the present disclosure. In this application scenario, the light-emitting mesa or epitaxial layer of the micro-LED chip 600 has an upside-down arranged trapezoidal structure, i.e., its light-emitting mesa is a structure with a larger upper surface and a smaller lower surface, consequently, the reflective mirror layer 200 is arranged to surround all side surfaces of the light-emitting mesa in the insulating layer and cover its bottom surface, so that the light reflection area is maximized, and thus improving the luminous efficiency of the micro-LED is improved.

The various components of the micro-LED chip 600 are described in detail below.

As shown in FIG. 5, the micro-LED chip 600 according to the present disclosure includes an upper stacked layer 600A and a lower stacked layer 600B, where the upper stacked layer 600A and the lower stacked layer 600B are formed into a complete micro-LED chip 600 through hybrid bonding at interface A. The structure and components of the upper stacked layer 600A and the lower stacked layer 600B are described in detail below.

### Upper stacked layer

The upper stacked layer 600A includes a first insulating layer 611A, a light-emitting mesa 601, a top transparent conductive layer 608, a first electrode 604 (cathode), a first through-hole contact portion 602, a second electrode 610 (anode), a first bonding mark 609A, and microlens 605. The various components are described below, respectively.

The first insulating layer 611A is configured to accommodate at least a part of the light-emitting mesa 601 and provide electrical insulation for it. Herein, the first insulating layer 611A has a recess 607 configured to accommodate the light-emitting layer and the second epitaxial layer of the light-emitting mesa 601, as well as the ancillary structures. For a detailed description of the light-emitting mesa 601 and its ancillary structures (such as the passivation layer 612, the reflective mirror layer 615, etc.), reference may be made to the light-emitting mesa 601 and description thereof. Herein, it should be noted that the recess 607 may be formed after the light-emitting mesa 601, i.e., the light-emitting mesa 601 and its ancillary structures are first formed on a temporary substrate, then the first insulating layer 611A surrounding them is formed on the light-emitting mesa and its ancillary structures. The material of the first insulating layer 611A may be, for example, silicon dioxide, silicon nitride, high-k dielectric materials (such as hafnium oxide, aluminum oxide, etc.), and so on. Methods for forming the first insulating layer 611A may include thermal oxidation, chemical vapor deposition (CVD), etc. The thickness of the first insulating layer 611A is, for example, 1 to 3 μm, preferably 2 μm, and more preferably 0.6 to 1.4 μm. Furthermore, the first insulating layer 611A may be planarized at interface A (e.g., through chemical mechanical polishing CMP) to facilitate hybrid bonding with the second insulating layer 611B.

The first insulating layer 611A is transparent to light emitted from the light-emitting mesa 601. In some embodiments, the first insulating layer 611A is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (H_{f}O₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the first insulating layer 611A may facilitate the passage of light emitted from the light-emitting mesa 601. In some embodiments, the first insulating layer 611A may include a plurality of portions, such as three embedded dielectric portions and two adhering dielectric portions. The embedded dielectric portions refer to the dielectric layers surrounding each light emitting diode structure; while the adhering dielectric portions refer to the dielectric layers between two light emitting diode structures. The embedded dielectric portions and the adhering dielectric portions may have the same or different compositions.

Light-emitting mesa 601 is configured to emit light, where the top surface (i.e., upper surface) area of the light-emitting mesa 601 is greater than the bottom surface (i.e., lower surface) area of the light-emitting mesa 601, the light-emitting mesa 601 is in the shape of an upside-down arranged trapezoid. The inclination angle of the light-emitting mesa 601 may be, for example, 10° to 85°, preferably 30° to 70°, and particularly 35° to 50°. The light-emitting mesa 601 includes a first epitaxial layer 601A, a light-emitting layer 601B, and a second epitaxial layer 601C, where the first epitaxial layer 601A is arranged on the top surface or the upper surface of the light-emitting mesa, i.e., the side facing the light extraction surface; the light-emitting layer 601B is arranged in the recess 607 and arranged between the first epitaxial layer 601A and the second epitaxial layer 601C; and the second epitaxial layer 601C is arranged on the bottom or lower surface of the light-emitting mesa 601, i.e., the side facing the drive backplane 606. The light-emitting layer 601B may include, for example, a multi-quantum-well layer and an electron barrier layer. In one embodiment of the present disclosure, the first epitaxial layer 601A is an N-type GaN layer or an N-type AlGaN layer, and the second epitaxial layer 601C is a P-type GaN layer or a P-type AlGaN layer, i.e., the material of the second epitaxial layer is a material layer of a second conductivity type including two or more elements of Ga, N, As, Al, In, and P, and the first epitaxial layer is a material layer of a first conductivity type including two or more elements of Ga, N, As, Al, In, and P. The multi-quantum-well layer is an InGaN/GaN multi-quantum-well layer, an InGaN/AlGaN multi-quantum-well layer, or an InGaAs/AlGaAs multi-quantum-well layer. The electron barrier layer is arranged on the first side of the light-emitting layer, and the first side refers to the side along which electrons migrate out of the light-emitting layer. In yet another embodiment of the present disclosure, the first epitaxial layer may also be a P-type GaN layer or a P-type AlGaN layer, and the second epitaxial layer is an N-type GaN layer or an N-type AlGaN layer. The top width of the light-emitting mesa 601 is, for example, 0.5 to 3 μm, preferably 1.0 to 2.0 μm. The thickness of the first epitaxial layer 601A is, for example, 4000 to 5000 angstroms, the thickness of the light-emitting layer 601B is, for example, 3500 to 4000 angstroms, and the thickness of the second epitaxial layer 601C is, for example, 2500 to 3500 angstroms. 1 angstrom = 10^(-10) m. From FIG. 5, it can also be seen that the first epitaxial layer 601A is located outside the recess 607, while the light-emitting layer 601B and the second epitaxial layer 601C are located within the recess 607, therefore, the surface area of the first epitaxial layer 601A is not limited by the aperture area of the recess 607 but can be significantly greater than the aperture area of the recess 607, thereby significantly increasing the area and thickness of the first epitaxial layer 601A; furthermore, due to the fact that merely the light-emitting layer 601B and the second epitaxial layer 601C need to be accommodated in the recess 607, these two layers have a larger area and thickness compared to the structure that requires accommodating three layers in the prior art, and thus the area and thickness of the epitaxial layer 601 are better increased, and the light output is improved. It can also be seen herein that the first epitaxial layer 601A passes through the first electrode 604 (herein is the cathode) from below the first electrode 604, so that the first epitaxial layers 601A of adjacent light-emitting mesas 601 can be connected to each other, and thus in the case of a common-cathode structure (i.e., where the first epitaxial layers of all micro-LEDs in the same array are connected to a common cathode), compared to the case where it is connected to the cathode 604 solely by the top transparent conductive layer 608 covering it, the conductivity between the cathode 604 and the first epitaxial layer 601A can be significantly enhanced, thereby increasing its power supply. Furthermore, the contact cross-section between the first epitaxial layer 601A and the cathode 604 at the edge is partially planar and partially inclined surface. The inclined surface increases the contact area between the first epitaxial layer 601A and the cathode 604 compared to a vertical surface, and thus the conductivity is increased.

The light-emitting mesa 601 also includes ancillary structures such as passivation layers 612 and 613, a reflective mirror layer 615, and a bottom transparent conductive layer 618, etc. The passivation layer 612 is arranged between the light-emitting mesa 601 and the reflective mirror layer 615, and optionally extends on the upper surface of the first insulating layer 611A, and the passivation layer 613 is arranged between the inner wall of the recess 607 and the reflective mirror layer 615, and optionally extends on the upper surface of the first insulating layer 611A. In another embodiment, merely one of the passivation layers 612 and 613 extends on the upper surface of the first insulating layer 611A, or neither does not extend over the upper surface of the first insulating layer 611A, instead, they extend merely until the upper surface of the first insulating layer 611A, while the upper surface of the first insulating layer 611A is covered by another insulating layer or dielectric layer. The function of passivation layers 612 and 613 is not only to reduce current leakage at the sidewalls, but also to passivate sidewall defects and block damage to the light-emitting mesa caused by water, oxygen, etc., during operation, they can also prevent metal diffusion from the reflective mirror layer 615, the cathode 604 etc. to the first insulating layer 611A or the light-emitting mesa 601. The passivation layers 612 and 613 may be formed by depositing SiO₂ material using a CVD process, and also may be formed by depositing Al₂O₃ material using an ALD process. The bottom transparent conductive layer 618 is arranged between the second epitaxial layer 601C and the reflective mirror layer 615. The bottom transparent conductive layer 618 is configured to electrically connect the second epitaxial layer 601C of the light-emitting mesa 601 to the reflective mirror layer 615 and further to the through-hole contact portion 602. The material of the bottom transparent conductive layer 618 is, for example, metal oxide such as indium tin oxide ITO or zinc oxide ZnO, etc., its formation methods include, for example, physical vapor deposition (PVD), chemical vapor deposition (CVD), sol-gel method, solution coating method, etc.

The reflective mirror layer 615 is configured to reflect light from the light-emitting mesa 601 upward. For this purpose, the reflective mirror layer 615 has an inclined surface on the side facing the light-emitting mesa 601, the inclination angle of this surface is, for example, the same as the inclination angle of the light-emitting mesa, of 10° to 85°, preferably 30° to 70°, particularly 35° to 50°.

Herein, the reflective mirror layer 615 includes a side reflective mirror layer 615A, a bottom reflective mirror layer 615B and an edge portion 615C, where the side reflective mirror layer 615A and the bottom reflective mirror layer 615B constitute the main body portion of the reflective mirror layer 615. The side reflective mirror layer 615A covers at least a part of the side surface of the light-emitting mesa 601. Both the side reflective mirror layer 615A and the bottom reflective mirror layer 615B are configured to reflect light from the light-emitting mesa 601 upward, while the bottom reflective mirror layer 615B is also configured to electrically connect the bottom transparent conductive layer 618 with the first through-hole contact portion 602. In the present embodiment, the side reflective mirror layer 615A covers the side surface of the part of the light-emitting mesa 601 within the recess 607, and the side reflective mirror layer 615A is formed between the passivation layer 612 and the inner wall of the recess 607 of the insulating layer. Due to the presence of the passivation layer 612, the side reflective mirror layer 615A may or may not have an atomic layer deposition layer on the side facing the light-emitting mesa 601. In the case of having an atomic layer deposition layer, it is possible to further prevent the metal in the reflective mirror layer 615 from penetrating into the light-emitting mesa 601 through the passivation layer 612. The side reflective mirror layer 615A has an inclined surface on the side facing the light-emitting mesa 601 to reflect light from the light-emitting mesa upward, the inclination angle of the inclined surface is, for example, the same as the inclination angle of the light-emitting mesa 601, of 10° to 85°, preferably 30° to 70°, and especially 35° to 50°. The bottom reflective mirror layer 615B covers at least a part of the bottom surface of the light-emitting mesa 601. In the present embodiment, the bottom mirror 615B covers the bottom transparent conductive layer 618 of the light-emitting mesa 601. The bottom reflective mirror layer 615B has an atomic layer deposition layer on the side facing the light-emitting mesa 601. The atomic layer deposition layer can block metal from the reflective metal layer to prevent its diffusion while substantially not affecting light reflection.

As can be seen from FIG. 5, the edge portion 615C of the reflective mirror layer 615 is disconnected from each other between adjacent light-emitting mesas 601 to prevent short circuits. Meanwhile, at the edge of the reflective mirror layer 615, there is also the edge portion 615C that is curved or inclined toward the lower surface of the light-emitting mesa, such that the edge of the reflective mirror layer 615 can be away from conductive structures, such as epitaxial layers on the upper surface of the light-emitting mesa 601, so that the risk of short circuits is reduced, that is to say, this configuration reduces the area of the edge portion 615C of the reflective mirror layer 615 exposed from the first insulating layer 611A surrounding the light-emitting mesa 601, meanwhile, it can also ensure that the reflective mirror layer 102 has sufficient thickness at the upper surface A of the light-emitting mesa 101, thus sufficient coverage at the edge is ensured and the quality of edge coverage is improved.

The reflective mirror layer 200 includes, from top to bottom (i.e., from the side facing the light-emitting mesa 601 to the side facing away from the light-emitting mesa 601) an atomic layer deposition layer 201, a reflective metal layer 202, a first barrier layer 203, and a second barrier layer 204, where the upper side of the reflective mirror layer 200 faces the light-emitting mesa or epitaxial layer of the micro-LED, and the lower side of the reflective mirror layer 200 faces away from the light-emitting mesa or epitaxial layer of the micro-LED or faces the bottom transparent conductive layer.

For example, the stacked layer structure of the reflective mirror layer 615 is as follows (in an order from close to the light-emitting mesa to far away from the light-emitting mesa):

Atomic layer deposition layer 201, the material of which is nickel, the thickness is 5 angstroms;

Reflective metal layer 202, the material of which is silver, the thickness is 1000 angstroms;

First and second barrier sublayers 203A and 203B, the materials are titanium and platinum, respectively, the thicknesses are 200 and 500 angstroms, respectively;

Second barrier layer 204, the material of which is titanium, the thickness is 200 angstroms.

Furthermore, the number of the first barrier layer 203 is 3.

The reflective mirror layer 615 can be formed, for example, through methods such as evaporation, sputtering, or chemical vapor deposition (CVD), etc., where the atomic layer deposition layer 201 of the reflective mirror layer 615 is formed by atomic layer deposition. The thickness of the passivation layer 612 between the reflective mirror layer 615 and the light-emitting mesa 601 is 800 to 2000 angstroms, preferably 1000 to 1600 angstroms. The thickness of the passivation layer 613 between the reflective mirror layer 615 and the inner wall of the recess 607 is 200 to 800 angstroms, preferably 300 to 600 angstroms.

The top transparent conductive layer 608 is arranged on the first epitaxial layer 601A and electrically connects the first electrode 604 (cathode) with the first epitaxial layer 601A. Herein, the top transparent conductive layer 608 extends on the first epitaxial layer 601A and fully covers the first epitaxial layer 601A, thereby providing more uniform power supply for the first epitaxial layer 601A. In other embodiments, the top transparent conductive layer 608 may merely partially cover the first epitaxial layer 601A. Furthermore, the top transparent conductive layer 608 extends below the first electrode 604, which is the cathode in this case, such that the transparent conductive layer 608 extends continuously on the first epitaxial layer 601A of adjacent light-emitting mesas 601A, so that the coverage area for the first epitaxial layer 601A is increased. The material of the top transparent conductive layer 608 is, for example, metal oxide such as indium tin oxide ITO or zinc oxide ZnO, etc. Its formation methods, for example, include physical vapor deposition (PVD), chemical vapor deposition (CVD), sol-gel method, solution coating method, etc.

The first electrode 604, herein is the cathode, and is arranged to surround the light-emitting mesa 601. The cathode 604 and its connecting components may be made of materials such as metals (such as silver, gold, or platinum), graphene, ITO, aluminum doped zinc oxide (AZO) or fluorine doped tin oxide (FTO), or any combination of the above materials. In yet another embodiment of the present disclosure, the cathode 604 and its connecting components may be made of non-transparent or transparent conductive materials, such as indium tin oxide (ITO). In a preferred embodiment, the cathode 604 is made of a reflective metal (such as copper, silver or aluminum), so that the cathode 604 can optically isolate adjacent light-emitting mesas 601 from each other and meanwhile also can reflect light from the light-emitting mesas 601, for example, reflect the light upward to the microlens 605, thereby increasing light output. In another embodiment, a reflective layer, such as a silver layer, may be coated onto the surface of the cathode 604 to provide reflective capability. Herein, the surface of the cathode 604 facing the light-emitting mesa 601 is an inclined surface, and it is inclined towards two sides (i.e. inclined from the bottom surface towards two sides), so that the light falling on it can be reflected upward, i.e. towards the light extraction side. Furthermore, the cathode 604 may be divided into an edge cathode 604A and a central cathode 604B, where the edge cathode 604A is arranged between the second electrode 610 (herein is the anode) and the outermost light-emitting mesa 601, where a part of the edge cathode 604A is arranged on the passivation layer 612, and another portion is arranged on the top transparent conductive layer 608, while the central cathode 604B is arranged between adjacent light-emitting mesas 601, where the central cathode 604B is arranged on the top transparent conductive layer 608. In this way, the edge cathode 604A can completely cover the side surface of the first epitaxial layer 601A and be in electrical contact with it, thereby increasing the electrical contact area between the cathode 604 and the first epitaxial layer 601A.

The first through-hole contact portion 602 is electrically connected with the bottom of the light-emitting mesa 601 and passes through the first insulating layer 611A. The first through-hole contact portion 602 is used for hybrid bonding with the second through-hole contact portion 603, and thus electrically connects the bottom of the light-emitting mesa 601, particularly the second epitaxial layer 601C to the second electrode 610 (herein it is the anode). The first through-hole contact portion 602 is preferably a cylindrical through-hole, and the inner wall and/or central space is filled with a conductor, such as metallic copper. The diameter of the first through-hole contact portion 602 is of 0.3 to 2 μm, preferably 0.6 to 1.4 μm. The first through-hole contact portion 602 may be planarized at interface A (e.g., through chemical mechanical polishing CMP) to facilitate hybrid bonding with the second through-hole contact portion 603. Furthermore, in order to enhance the bonding strength and improve the conductivity between the first through-hole contact portion 602 and the second through-hole contact portion 603, a first interface metal layer may be arranged at the first aperture of the first through-hole contact portion 602, and the area of the first interface metal layer is greater than the area of the first aperture. Similarly, a second interface metal layer may be arranged at the second aperture of the second through-hole contact portion, and the area of the second interface metal layer is greater than the area of the second aperture. The areas of the first interface metal layer and the second interface metal layer may be equal, or the area of the first interface metal layer may be greater or less than the area of the second interface metal layer. After the first interface metal layer and the second interface metal layer 202 are bonded to each other, the formed bonding surface is greater than the bonding surface formed by directly bonding the first aperture of the first through-hole contact portion 602 and the second aperture 204 of the second through-hole contact portion 603, and thus the bonding strength is enhanced and the conductivity between the first through-hole contact portion 602 and the second through-hole contact portion 603 is improved. The first interface metal layer 201 and the second interface metal layer 202 are made of, for example, a conductive metal such as copper. Their formation methods may include, for example, physical vapor deposition (PVD), chemical vapor deposition (CVD), electroplating, chemical plating, and so on. The formation method of the first through-hole contact portion 602 may be, for example, as follows: a light-emitting mesa 601 and a first insulating layer 611A are formed on a temporary substrate, then the first insulating layer 611A is etched to form through-holes leading to the bottom of the light-emitting mesa 601, subsequently, a metal is deposited in the through-holes, and finally the apertures of the through-holes are planarized to form the bonding surface.

Furthermore, the first through-hole contact portion 602 is used to electrically connect the drive backplane 606 with the bottom (herein is the reflective mirror layer 615) of the epitaxial layer 601 (or light-emitting mesa) of the micro-LED array after bonding with the second through-hole contact portion 603, thereby connecting the epitaxial layer 601 to the anode 610. Herein, a first metal barrier layer 617 is arranged between the first through-hole contact portion 602 and the reflective mirror layer 615. The first metal barrier layer 617 can prevent the metal in the first through-hole contact portion 602 from diffusing into the epitaxial layer 601 or the first insulating layer 611A through the reflective mirror layer 615 and other layers (e.g., the bottom transparent electrode layer) that may be arranged therebetween, or from oxidizing. If the metal in the first through-hole contact portion 602 diffuses into the epitaxial layer 601, then the luminous performance of the epitaxial layer 601 will be affected; if it diffuses into the first insulating layer 611A, then the insulating effect of the first insulating layer 611A will be affected, thereby leading to leakage current or even short circuits; if the metal in the first through-hole contact portion 602 oxidizes, then it may cause poor contact between the first through-hole contact portion 602 and the reflective mirror layer 607, or even result in an open circuit in the electrical lines to the epitaxial layer 601. From this, it can be seen that by arranging the first through-hole contact portion 602 according to the present disclosure, metal diffusion in the first through-hole contact portion 602 can be effectively avoided, and thus risks such as reduced luminous performance, short circuit, and open circuit, etc. of the micro-LED can be effectively prevented. The combination of the first metal barrier layer 617 and the first barrier layer 203 and the second barrier layer 204 of the reflective mirror layer can further enhance the metal barrier and antioxidant effects.

The second electrode 610, herein is the anode, and is electrically connected with the drive backplane 606 through a third through-hole contact portion 614 passing through the first insulation layer 611A and the second insulation layer 611B. The anode 610 may be, for example, connected to an external power source or control source for supplying power for the micro-LED chip 600 or controlling the micro-LED chip 600. Herein, the third through-hole contact portion 614 may include a plurality of through-hole contact portions for connecting the second epitaxial layers 601C of a plurality of light-emitting mesas to the anode 610. Herein, it is exemplarily shown that the third through-hole contact portion 614 includes two through-hole contact portions, but this is merely an example, and other numbers of third through-hole contact portions 614 are also conceivable. The third through-hole contact portion 614 may be formed either before hybrid bonding or after hybrid bonding. If the third through-hole contact portion 614 is formed before hybrid bonding, then the upper and lower portions of the third through-hole contact portion 614 are first formed in the upper stacked layer 600A and the lower stacked layer 600B, respectively, then after hybrid bonding, these two portions are interconnected to form the third through-hole contact portion, and then the first insulating layer 611A is etched from above to form the anode 610 on the third through-hole contact portion 614. If the third through-hole contact portion 614 is formed after hybrid bonding, then the first insulating layer 611A is etched from above to form through-holes leading to the drive backplane 606, metal is then deposited in the through-holes, then the third through-hole contact portion 614 is etched to form a recess, metal is then deposited in the recess to form the anode 610. The anode 610 and its connecting components may be made of materials such as metals (e.g., copper, silver, or aluminum), graphene, ITO, aluminum doped zinc oxide (AZO), or fluorine doped tin oxide (FTO), or any combination of the above materials.

The first bonding mark 609A is arranged in the first insulating layer 611A and exposes the first marking surface, i.e., the aperture of the first bonding mark. The function of the first bonding mark 609A in the upper stacked layer 600A is to serve as a mark aligned with the second bonding mark 609B in the lower stacked layer 600B, and thus precise hybrid bonding is achieved, where the second bonding mark 609B is arranged in the second insulating layer 611B and exposes the second marking surface, i.e., the aperture of the second bonding mark. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

Microlens 605 is arranged above the light-emitting mesa 601 for shaping such as focusing or collimating the light emitted therefrom. The microlens includes a lens portion 605A and a spacer portion 605B. The lens portion 605A is arranged at the outermost side, i.e., the topmost and configured to shape light from the light-emitting mesa 601. The spacer portion 605B is arranged between the lens portion 605A and the light-emitting mesa 601 to adjust the focal position of the lens portion 605A, for example, parameters such as the thickness of the spacer portion 605B and the curvature of the lens portion 605A, etc. Are adjusted, such that the focal point of the lens portion 605A is precisely located in the light-emitting mesa 601 of the micro-LED. The width of the microlens 605 is, for example, 0.8 to 4 μm, preferably 1 to 3 μm. The distance between the lens portion 605A and the cathode 604 is, for example, 0.05 to 4 μm, preferably 0.1 to 0.3 μm. The microlens 605 corresponds one-to-one with the light-emitting mesa 601. Meanwhile, in the present embodiment, adjacent microlenses 605 have gaps between them and their bottoms are connected with each other. The bottoms of the gaps are higher than the top of the light-emitting mesa 601 or higher than the bottom of the light-emitting layer 601B of the light-emitting mesa 601, and the lens portion 605A is located above the cathode 604. The microlens 605 may be formed through a plurality of deposition steps, and during the formation process of the microlens, a SiO₂ film layer is first deposited, then ion etching is performed, and the microlens is formed at positions on the surface of the top transparent conductive layer 608 corresponding to each light-emitting mesa 601.

### Lower stacked layer

The lower stacked layer 600B includes a second insulating layer 611B, a second through-hole contact portion 603, a drive backplane 606, and a second bonding mark 609B. The various components are described below, respectively.

The second insulating layer 611B is arranged on the drive backplane 606 and is configured to accommodate the second through-hole contact portion 603. The material of the second insulating layer 611B may be, for example, silicon dioxide, silicon nitride, high-k dielectric materials (e.g., hafnium oxide, aluminum oxide, etc.), and so on. The second insulating layer 611B may be, for example, formed on the drive backplane 606 through methods such as thermal oxidation or chemical vapor deposition (CVD), etc. The thickness of the second insulating layer 611B may be, for example, 1 to 3 μm, preferably 2 μm, and more preferably 0.6 to 1.4 μm. Furthermore, the second insulating layer 611B may be planarized at interface A (e.g., through chemical mechanical polishing CMP) to facilitate hybrid bonding with the first insulating layer 611A.

The second insulating layer 611B is transparent to light emitted from the light-emitting mesa 601. In some embodiments, the second insulating layer 611B is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the second insulating layer 611B may facilitate the passage of light emitted from the light-emitting mesa 601. In some embodiments, the second insulating layer 611B may include a plurality of portions, such as three embedded dielectric portions and two adhering dielectric portions. The embedded dielectric portions refer to the dielectric layers surrounding each light emitting diode structure; while the adhering dielectric portions refer to the dielectric layers between two light emitting diode structures. The embedded dielectric portions and the adhering dielectric portions may have the same or different compositions.

The second through-hole contact portion 603, which passes through the second insulating layer 611B. The second through-hole contact portion 603 is configured to hybrid bond with the first through-hole contact portion 602 at interface A, and thus electrically connect the bottom of the light-emitting mesa 601, particularly the second epitaxial layer 601C to the second electrode 610 (herein it is the anode). The second through-hole contact portion 603 is preferably a cylindrical through-hole, and the inner wall and/or central space is filled with a conductor, such as metallic copper. The diameter of the second through-hole contact portion 603 is of 0.5 to 2.2 μm, preferably 0.8 to 1.6 μm. The second through-hole contact portion 603 may be planarized at interface A (e.g., through chemical mechanical polishing CMP) to facilitate hybrid bonding with the first through-hole contact portion 602. Furthermore, in order to enhance the bonding strength and improve the conductivity between the second through-hole contact portion 603 and the first through-hole contact portion 602, a second interface metal layer may be arranged at the second aperture of the second through-hole contact portion 603, and the area of the second interface metal layer is greater than the area of the second aperture. Similarly, a first interface metal layer may be arranged at the first aperture of the first through-hole contact portion 602, and the area of the first interface metal layer is greater than the area of the first aperture. The areas of the first interface metal layer and the second interface metal layer may be equal, or the area of the first interface metal layer may be greater or less than the area of the second interface metal layer. After the first interface metal layer and the second interface metal layer are bonded to each other, the formed bonding surface is greater than the bonding surface formed by directly bonding the first aperture of the first through-hole contact portion 602 and the second aperture of the second through-hole contact portion 603, and thus the bonding strength is enhanced and the conductivity between the first through-hole contact portion 602 and the second through-hole contact portion 603 is improved. The first interface metal layer and the second interface metal layer are made of, for example, a conductive metal such as copper. Their formation methods may include, for example, physical vapor deposition (PVD), chemical vapor deposition (CVD), electroplating, chemical plating, and so on. The formation method of the second through-hole contact portion 603 may be, for example, as follows: a drive backplane 606 is provided, then a second insulating layer 611B is formed on the drive backplane 606, then the second insulating layer 611B is etched to form through-holes leading to the top of the drive backplane 606, subsequently, a metal is deposited in the through-holes, and finally the apertures of the through-holes are planarized to form the bonding surface.

Furthermore, the second through-hole contact portion 603 is used to electrically connect the drive backplane 606 with the bottom (herein is the reflective mirror layer 615) of the epitaxial layer 601 (or light-emitting mesa) of the micro-LED array after bonding with the first through-hole contact portion 602, thereby connecting the epitaxial layer 601 to the anode 610. Herein, a first metal barrier layer 617 is arranged between the second through-hole contact portion 603 and the drive backplane 606. The first metal barrier layer 617 can prevent the metal in the second through-hole contact portion 603 from diffusing into the drive backplane 606 or the insulating layer 611B, or from oxidizing. If the metal in the second through-hole contact portion 603 diffuses into the drive backplane 606, then the electrical performance of the drive circuit will be affected, such as it causes a short circuit; if it diffuses into the insulating layer 611B, then the insulating effect of the insulating layer 611B will be affected, thereby leading to leakage current or even short circuits; if the metal in the second through-hole contact portion 603 oxidizes, then it may cause poor contact between the second through-hole contact portion 603 and the drive backplane 606, or even result in an open circuit in the electrical lines to the drive backplane 606. From this, it can be seen that by arranging the second through-hole contact portion 603 according to the present disclosure, metal diffusion in the second through-hole contact portion 603 can be effectively avoided, and thus risks such as short circuits or open circuits, etc. in the drive backplane 606 are effectively prevented. The combination of the first metal barrier layer 617 and the first barrier layer 203 and the second barrier layer 204 of the reflective mirror layer can further enhance the metal barrier and antioxidant effects.

The drive backplane 606 (or drive circuit) is electrically connected with the second through-hole contact portion 603 to electrically connect the second epitaxial layer 601C of the light-emitting mesa 601 to the anode 610. For this purpose, the drive backplane 606 has conductive line layers for interconnecting each second through-hole contact portion 603 to the corresponding anode 610. The drive backplane 606 may be, for example, a thin-film transistor TFT drive circuit and may include 2T1C drive circuit, 3T1C drive circuit, and 5T2C drive circuit. The drive backplane 606 is configured to drive the micro-LEDs, such as controlling the switching on/off and brightness of the micro-LEDs. The drive backplane 606 may include, for example, transistors, capacitors, a conductive line layer, an insulating layer, and a metal layer, etc. The conductive line layer is formed on the substrate and configured to supply power to the micro-LED array. The insulating layer is formed on the conductive line layer, where through-holes are arranged in the insulating layer, and through-hole contact portions (e.g., IC copper pillars) are arranged in the through-holes for electrically connecting the conductive line layer with the micro-LED array. The metal layer is used for bonding and electrically contacting the micro-LEDs. The conductive line layer, the metal layer, and the insulating layer may be formed on substrate through deposition methods such as physical vapor deposition (PVD) and chemical vapor deposition (CVD).

The second bonding mark 609B is arranged in the second insulating layer 611B and exposes the second marking surface, i.e., the aperture of the second bonding mark. The function of the second bonding mark 609B in the lower stacked layer 600B is to serve as a mark corresponding to the first bonding mark 609A in the upper stacked layer 600A, and thus precise hybrid bonding is achieved. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

After the formation of the lower stacked layer 600B and the upper stacked layer 600A, the lower stacked layer 600B is jointed with the upper stacked layer 600A through hybrid bonding, such that the first through-hole contact portion 602 is bonded with the second through-hole contact portion 603 and the first insulating layer 611A is bonded with the second insulating layer 611B, optionally the first bonding mark 609A is bonded with the second bonding mark 609B, and the upper and lower portions of the third through-hole contact portion 614 are bonded with each other. The present disclosure solves the technical problem encountered in manufacturing upside-down arranged trapezoidal light-emitting mesa with a large upper surface and a small lower surface, i.e., the problem of electrical connection of the light-emitting mesa to the driving circuit, by respectively fabricating the upper stacked layer 600A and the lower stacked layer 600B and then jointing them with each other through hybrid bonding. The present disclosure achieves electrical connection of the light-emitting mesa 601 to the drive backplane 606 through hybrid bonding, allowing both the upper stacked layer 600A and the lower stacked layer 600B to be manufactured from the surface opposed to the hybrid bonding surface, i.e., interface A, towards the hybrid bonding surface, so that high-quality conductive structures, such as the first to third through-hole contact portions (such as IC copper pillars) are achieved, and the length of the conductive structure can also be flexibly selected.

An exemplary of the hybrid bonding may include the following two parts:

(1) Dielectric-to-dielectric bonding (i.e., bonding between the first insulating layer 611A and the second insulating layer 611B): at room temperature, extremely flat and smooth dielectric surfaces obtained through chemical mechanical polishing (CMP) are brought into close contact at room temperature after activation through methods such as plasma treatment to achieve preliminary bonding.

(2) Metal-to-metal bonding (i.e., bonding between through-hole contact portions): after completing the dielectric-to-dielectric bonding, the upper and lower stacked layers are heated to 200-400°C for annealing treatment to strengthen the dielectric bonding and facilitate metal-to-metal bonding, thereby achieving hybrid bonding.

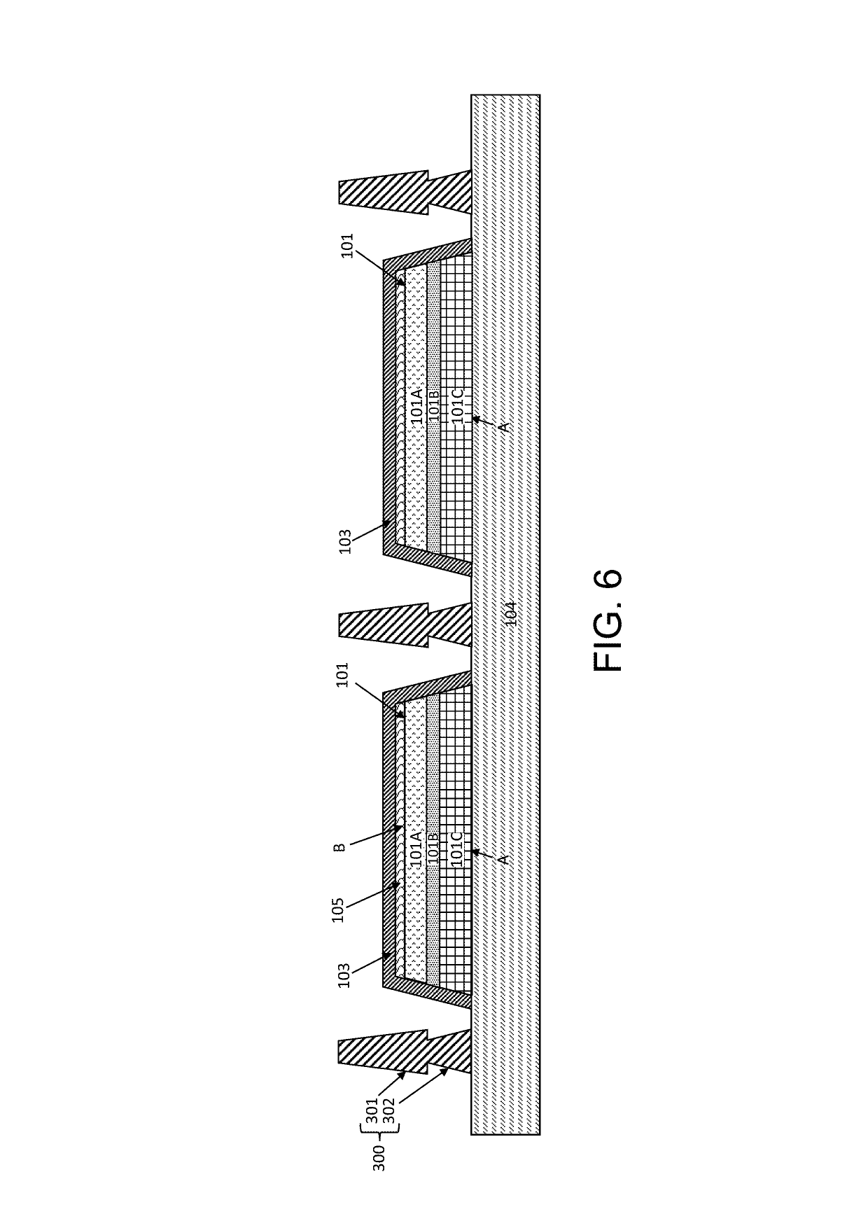

FIG. 6 illustrates a schematic diagram of a first embodiment of a photoresist ring 300 for forming the reflective mirror layer according to the present disclosure.

As shown in FIG. 6, the photoresist ring 300 for forming the reflective mirror layer according to the present disclosure includes an upper layer ring 301 and a lower layer ring 302. The function of the photoresist ring 300 is to act as a molded body when forming the reflective mirror layer on the light-emitting mesa 101, on the one hand, it isolates and disconnects the reflective mirror layers of adjacent light-emitting mesas 101 from each other; on the other hand, it shapes the reflective mirror layer to achieve a desired cross-sectional profile of the reflective mirror layer, such as a circle, a square, a rectangle, etc. The photoresist ring 300 includes an upper layer ring 301 and a lower layer ring 302, where the lower layer ring 302 is arranged to surround the light-emitting mesa 101 of the micro-LED, and the upper layer ring 301 is arranged on the lower layer ring 302, where at the connection portion between the upper layer ring 301 and the lower layer ring 302, the thickness of the upper layer ring 301 is greater than the thickness of the lower layer ring 302. For example, at the connection portion between the upper layer ring and the lower layer ring, the thickness of the upper layer ring is greater than the thickness of the lower layer ring by 20% to 60%. Such thickness jump facilitates the formation of an overhang layer of the reflective mirror layer at the connection portion, and the overhang layer is separated from the lower layer ring 302, and a notch of the reflective mirror layer exists below the overhang layer, where the notch permits the stripping solution to enter and erode the bottom of the lower layer ring 302 during the stripping process, so that the lower layer ring 302 is separated from the temporary substrate 104, and the separated lower layer ring 302 will carry away the upper layer ring 301 and the reflective mirror layer covering thereon. The cleaned structure will not have the photoresist ring 300 but will have the formed reflective mirror layer.

The height of the lower layer ring 302 can affect the height of the edge portion of the reflective mirror layer and the height of the notch, the higher the height of the lower layer ring 302, the higher the edge portion and the higher the notch. For example, in the present embodiment, the height of the lower layer ring 302 is two-thirds of the height of the light-emitting mesa 101, or the height of the lower layer ring 302 is the same as the height of the light-emitting layer 101B of the light-emitting mesa 101. In this way, the height of the edge portion of the formed reflective mirror layer is lower, so that the formed reflective mirror layer substantially corresponds to the contour of the light-emitting mesa, such as a flat-topped conical shape. Meanwhile, since the lower layer ring 302 is relatively low, the formed notch is also lower, which facilitates the entry of stripping solution. The longitudinal cross-sectional shapes of the upper layer ring 301 and the lower layer ring 302 in a longitudinal cross-section perpendicular to the upper surface of the light-emitting surface can be trapezoid or triangle. Under the teachings of this invention, other shapes can also be conceived.

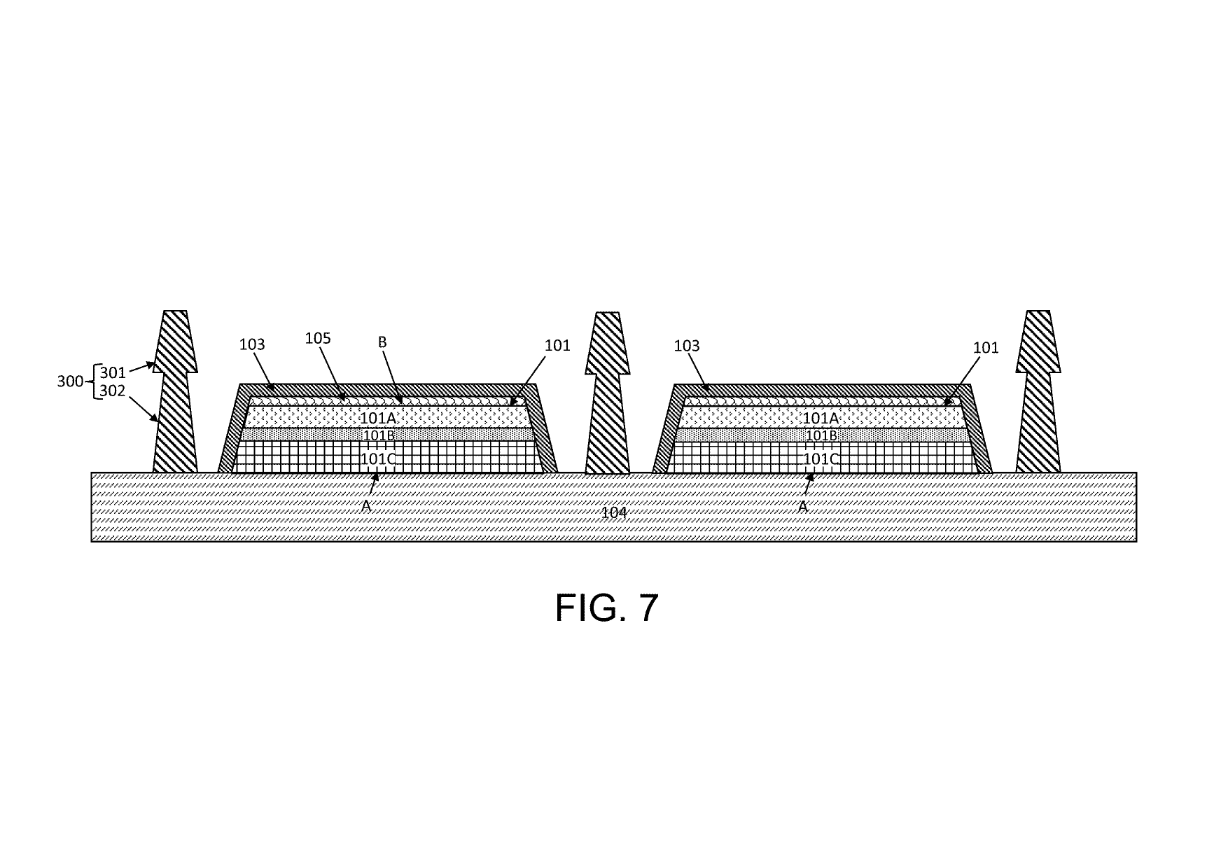

FIG. 7 illustrates a schematic diagram of a second embodiment of a photoresist ring 300 for forming the reflective mirror layer according to the present disclosure.

The second embodiment shown in FIG. 7 is substantially the same as the first embodiment shown in FIG. 6, and the main difference lies in, in the second embodiment, the height of the lower layer ring 302 is configured to be higher than the lower surface B of the light-emitting mesa. In this way, the edge portion of the formed reflective mirror layer has a height substantially the same as the light-emitting mesa, which can facilitate the cross-sectional shape of the molded reflective mirror layer. By making the cross-sectional shape of the lower layer ring 302 (the upper layer ring 301 having the same shape if necessary) in a cross-section parallel to the upper surface A of the light-emitting mesa 101 to be one of the following items: a triangle, a square, a rectangle, a circle, an ellipse, and an n-sided polygon, where n is an integer greater than 4, the formed reflective mirror layer can have the same cross-sectional shape, i.e., a triangle, a square, a rectangle, a circle, an ellipse, and an n-sided polygon. Preferably, the cross-sectional shape of the lower layer ring 302 (and the upper layer ring 301 if necessary) is square, and the square has rounded inner corners, such that the formed reflective mirror layer has a square cross-sectional shape, and the square has rounded outer corners.

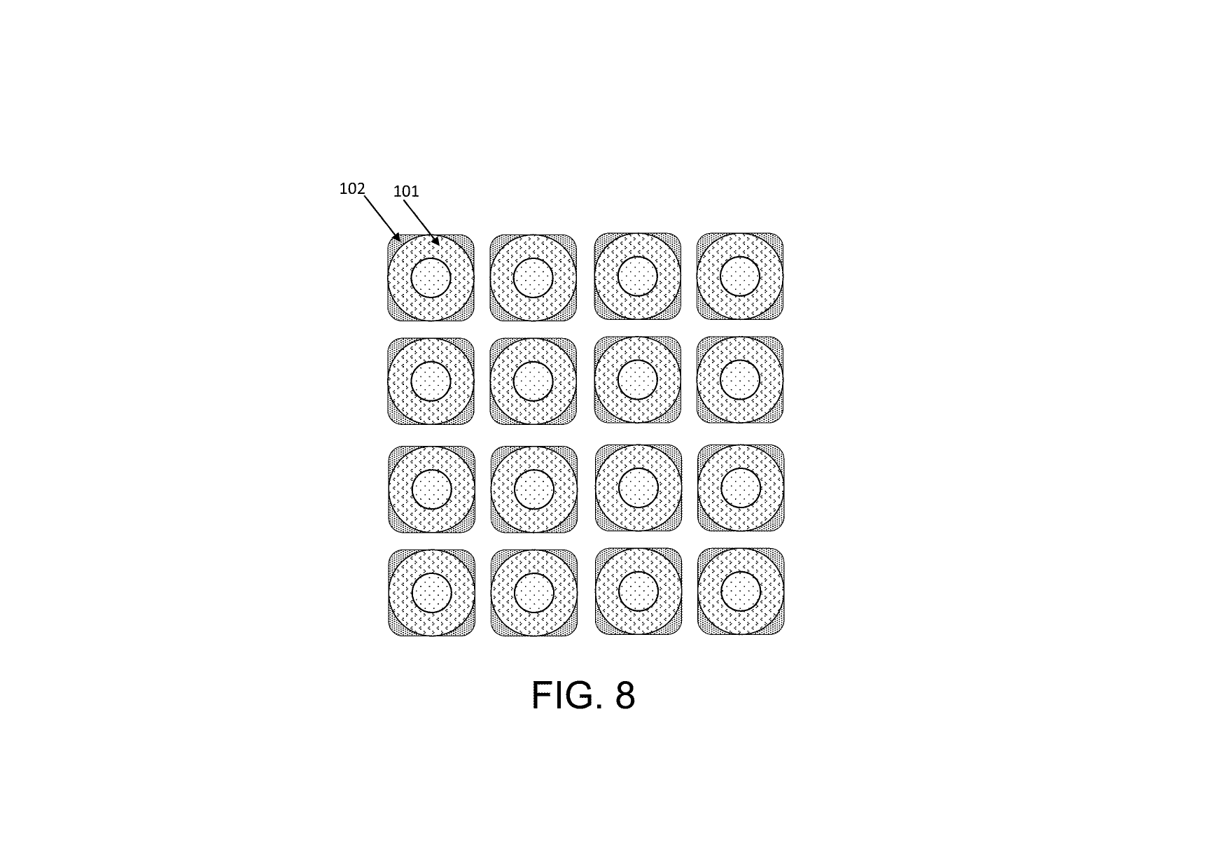

FIG. 8 illustrates a top view schematic diagram for forming the reflective mirror layer 102 according to the present disclosure.

As shown in FIG. 8, the reflective mirror layer 102 according to the present disclosure surrounds the light-emitting mesa 101 and has a square cross-sectional shape with rounded corners. This can be achieved through the following methods, for example, the photoresist ring of the reflective mirror layer has a square cross-sectional shape with rounded inner corners, and the bottom of the upper layer ring is flush with or higher than the lower surface of the light-emitting mesa. Similarly, by making the photoresist ring of the reflective mirror layer have other cross-sectional shapes, and the bottom of the upper layer ring is flush with or higher than the lower surface of the light-emitting mesa, a reflective mirror layer with the other cross-sectional shapes can be formed.

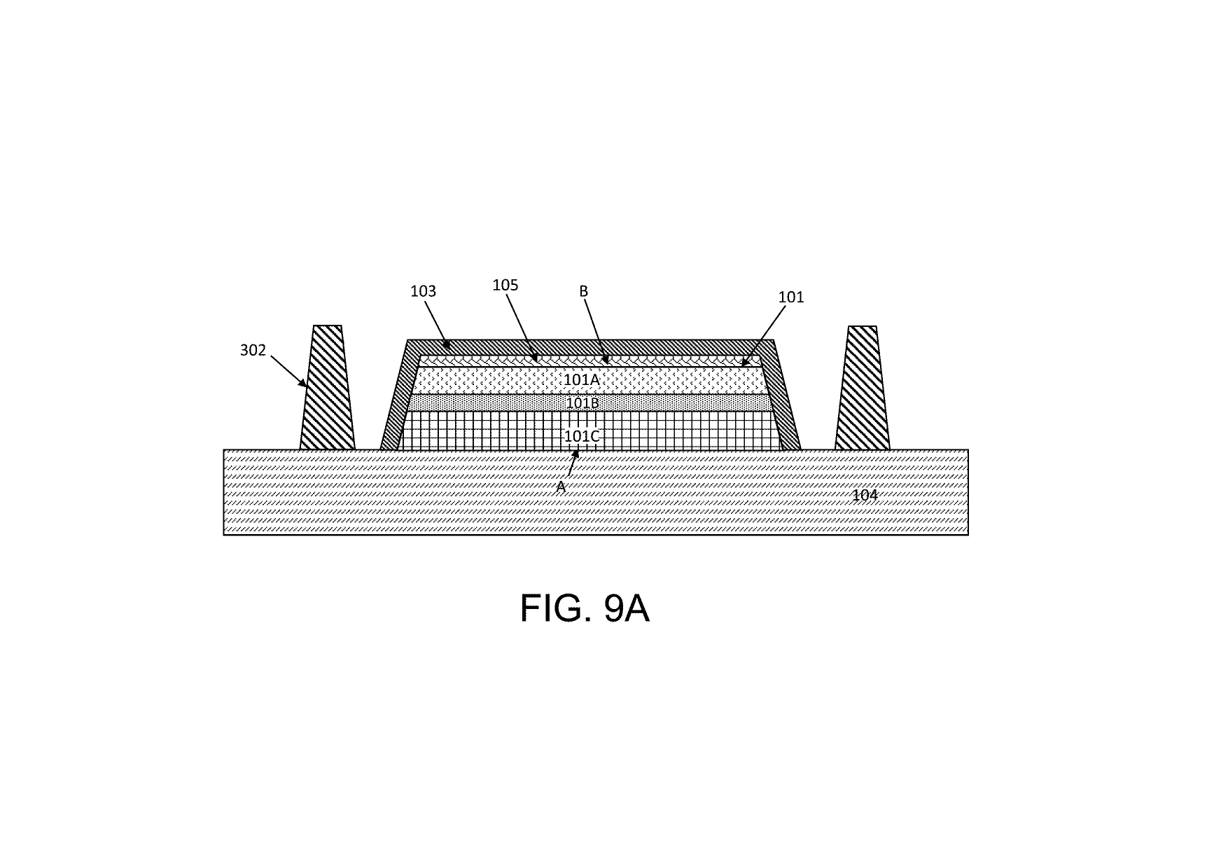

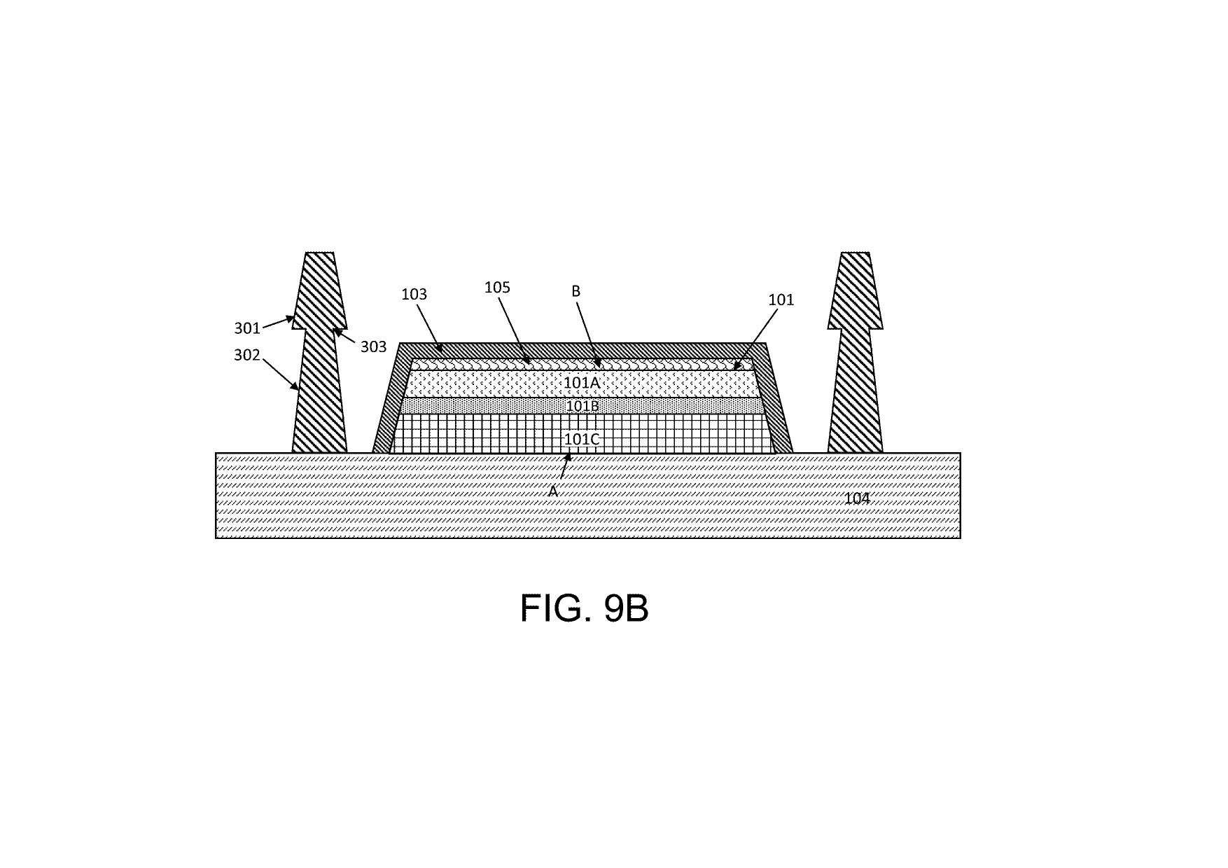

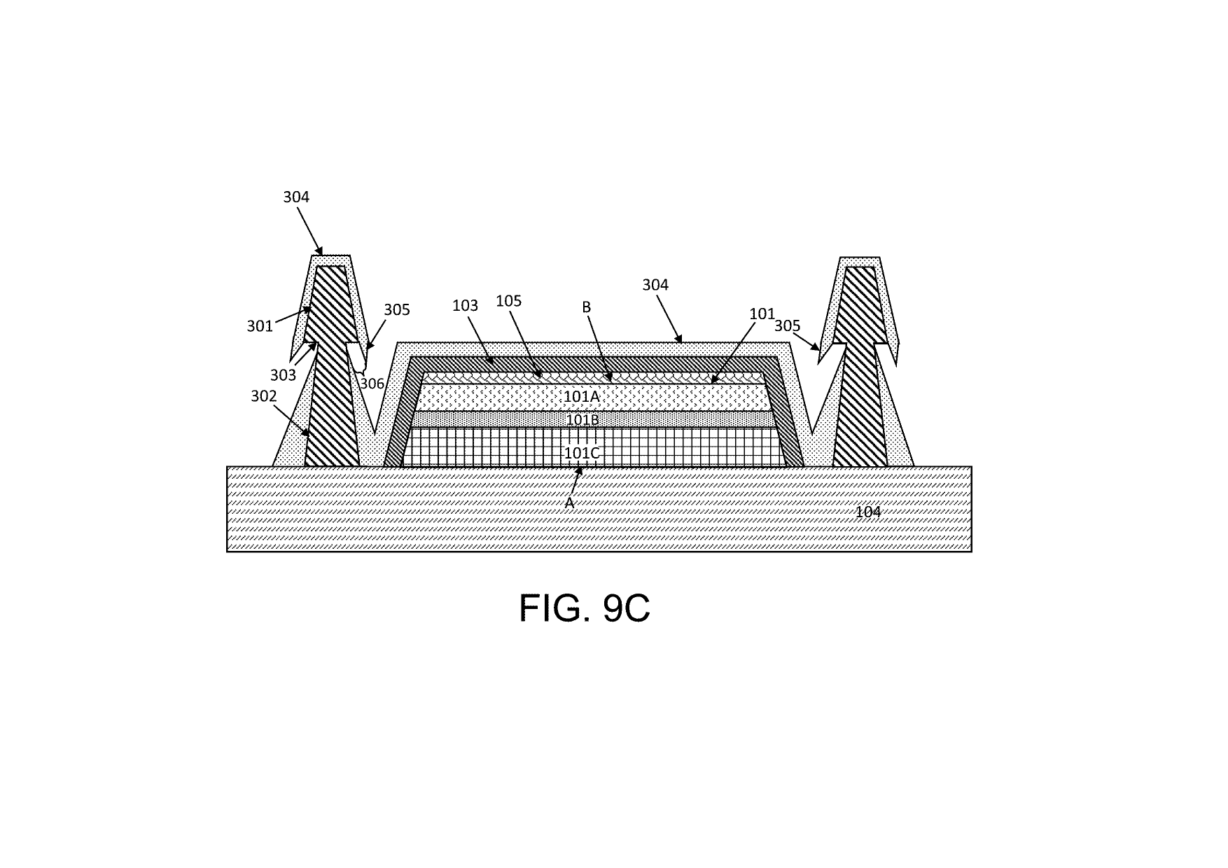

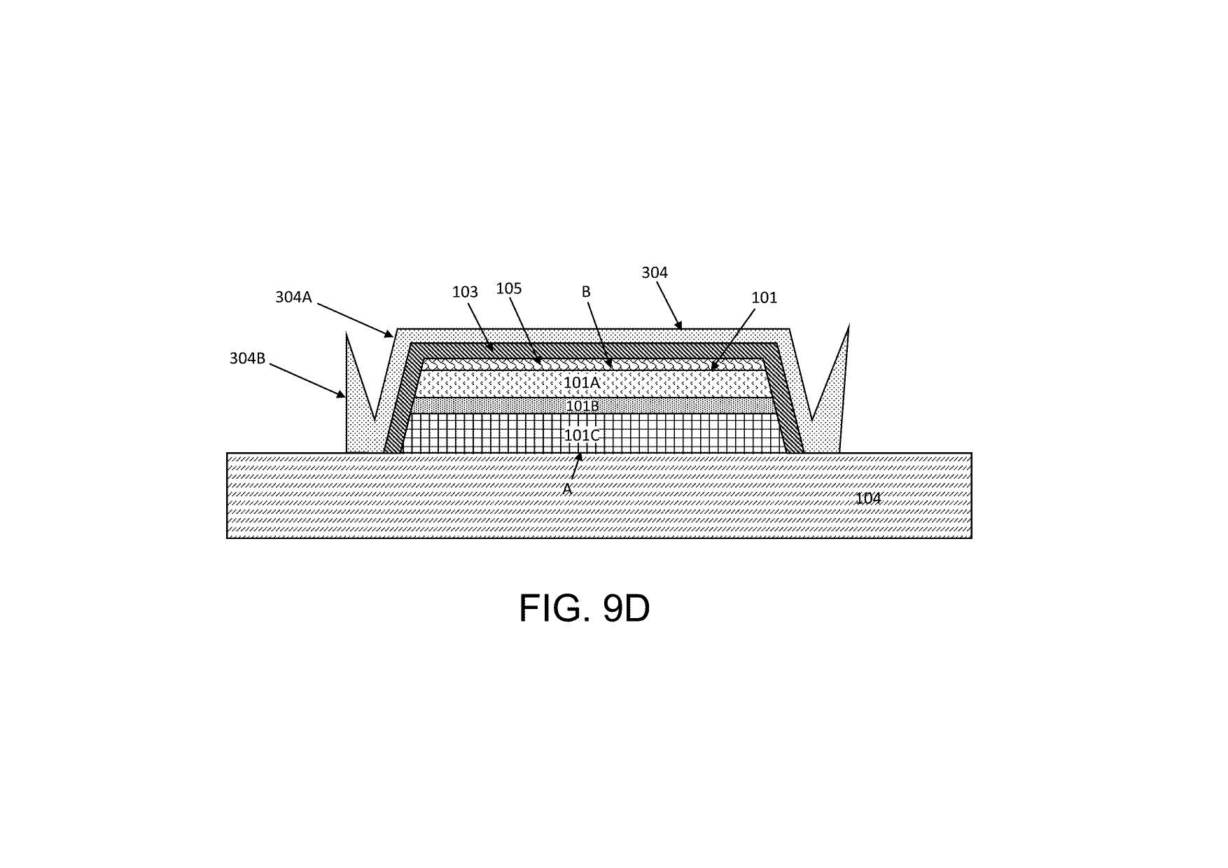

FIGS. 9A to 9D illustrate the steps of a method for forming the reflective mirror layer.

As shown in FIG. 9A, in step S1, a lower layer ring 302 is formed around the light-emitting mesa 101. This can be achieved by coating photoresist and performing exposure and development.

As shown in FIG. 9B, in step S2, an upper layer ring 301 is formed on the lower layer ring 302, where the thickness of the upper layer ring 301 is greater than the thickness of the lower layer ring 302 at the connection portion 303 between the upper layer ring 301 and the lower layer ring 302. This can be achieved by coating photoresist and performing exposure and development.

As shown in FIG. 9C, in step S3, a reflective mirror layer 304 is coated on the light-emitting mesa 101, the upper layer ring 301, and the lower layer ring 302, where the reflective mirror layer 304 forms, at the connection portion 303, an overhang layer 305 detached from the lower layer ring 302, and the lower layer ring 302 has a gap 306 below the overhang layer 305 that is not covered by the reflective mirror layer 304. The presence of the overhang layer results from a thickness difference between the upper layer ring 301 and the lower layer ring 302 at the connection portion 303, this is because the thickness difference causes the reflective mirror layer 304 to not adhere to the lower ring 302 during the downward flow, but instead forms a suspended overhang layer 305. Due to the effect of gravity, the overhang layer 305 can only support a certain length, and if it exceeds this length, it will break, thereby forming the gap 306. The gap 306 can permit the stripping solution to enter the root of the lower layer ring 302 during the stripping process, thus the lower layer ring 302 is reliably removed through the stripping solution, and meanwhile, the upper layer ring 301 on the lower layer ring 302 and the reflective mirror layer 304 attached to it are removed, therefore, complete removal of the photoresist molded body is achieved.

As shown in FIG. 9D, in step S4, the upper layer ring 301 and the lower layer ring 302 are removed. The process is to apply the stripping solution so that it enters the root of the lower layer ring 302. After a certain period of time, the stripping solution dissolves the lower layer ring 302 and makes it to be removed during the rinsing process, and meanwhile, the upper layer ring 301 on the lower layer ring 302 and the reflective mirror layer 304 attached to it can also be removed. From FIG. 9D, it can be seen that after the stripping step, the reflective mirror layer 304 has a main body portion 304A and an edge portion 304B.

Although some embodiments of the present disclosure have been described in the present application, however, those skilled in the art will appreciate that these embodiments are merely illustrated as examples. Numerous variation schemes, alternative schemes, and improvement schemes may be conceived by those skilled in the art in light of the teachings of the present disclosure without departing from the scope of the present disclosure. The appended claims are intended to define the scope of the present disclosure and thus encompass methods and structures within the scope of these claims themselves and their equivalent variations.

What is claimed is:

1. A reflective mirror layer for a micro-LED, wherein:
the reflective mirror layer is configured to reflect light from a light-emitting mesa toward a light extraction side, an area of an upper surface of the light-emitting mesa facing the light extraction side is greater than an area of a lower surface facing away from the light extraction side, wherein the reflective mirror layer comprises:
a main body portion configured to cover a lower surface of the light-emitting mesa and surround a side surface of the light-emitting mesa; and
an edge portion configured to connect with an edge of the main body portion and have an angle greater than 0° with the main body portion, wherein the edge portions of the reflective mirror layers of adjacent micro-LEDs are disconnected from each other.

2. The reflective mirror layer according to claim 1, wherein the angle ranges from 5° to 85°.

3. The reflective mirror layer according to claim 1, wherein:
a length of the edge portion ranges from 0.1 μm to 0.2 μm, and a thickness of the edge portion ranges from 0.2 to 0.4 μm; and/or
a thickness of the main body portion ranges from 0.2 μm to 0.5 μm; and/or
a lowermost side of the edge portion is flush with or not flush with the lower surface of the light-emitting mesa.

4. The reflective mirror layer according to claim 1, wherein the cross-sectional shape of the main body portion in a cross-section parallel to the upper surface of the light-emitting mesa is one of the following:
triangle, square, rectangle, circle, ellipse, or polygon with n sides, wherein n is an integer greater than 4.

5. The reflective mirror layer according to claim 4, wherein the cross-sectional shape of the main body portion is square, and the cross-sectional shape of the light-emitting mesa is circle, wherein the circle is an inscribed circle of the square and the circle has rounded outer corners.

6. The reflective mirror layer according to claim 1, wherein:
a lowest side of a connection portion provided between the edge portion and the main body portion has a distance of 0 to 0.8 μm from the upper surface of the light-emitting mesa; and/or
a distance between the edge portions of the reflective mirror layers of adjacent micro-LEDs ranges from 0.3 μm to 2 μm.

7. The reflective mirror layer according to claim 1, wherein the reflective mirror layer comprises, starting from a side facing the light-emitting mesa:
an atomic layer deposition layer, the material of the atomic layer deposition layer is selected from a group comprising the following items: nickel, platinum, titanium, and tantalum;
a reflective metal layer, the material of the reflective metal layer is selected from a group comprising the following items: silver, aluminum, and gold;
a first barrier layer comprising at least a first barrier sublayer and a second barrier sublayer, wherein the materials of the first barrier sublayer and the second barrier sublayer are respectively selected from a group comprising the following items: platinum, titanium, and tantalum; and
a second barrier layer, the material of the second barrier layer is selected from a group comprising the following items: platinum, titanium, and tantalum.

8. The reflective mirror layer according to claim 7, wherein the material of the second barrier layer is the same as the material of the first barrier sublayer.

9. The reflective mirror layer according to claim 7, wherein:
the material of the atomic layer deposition layer is nickel;
the material of the reflective metal layer is silver;
the materials of the first barrier sublayer and the second barrier sublayer are titanium and platinum, respectively; and
the material of the second barrier layer is titanium.

10. The reflective mirror layer according to claim 7, wherein:
a thickness of the atomic layer deposition layer ranges from 3 angstroms to 8 angstroms;
a thickness of the reflective metal layer ranges from 800 angstroms to 1200 angstroms;
a thickness of the first barrier sublayer ranges from 100 angstroms to 300 angstroms, and the thickness of the second barrier sublayer ranges from 400 angstroms to 600 angstroms; and
a thickness of the second barrier layer ranges from 100 angstroms to 300 angstroms.

11. A photoresist ring for forming the reflective mirror layer according to claims claim 1, wherein the photoresist ring forms the reflective mirror layer, and the photoresist ring comprises:
a lower layer ring surrounding the light-emitting mesa of the micro-LED; and
an upper layer ring located on the lower layer ring, wherein at a connection portion between the upper layer ring and the lower layer ring, a thickness of the upper layer ring is greater than a thickness of the lower layer ring.

12. The photoresist ring according to claim 11, wherein at the connection portion between the upper layer ring and the lower layer ring, the thickness of the upper layer ring is greater than the thickness of the lower layer ring by 20% to 60%.

13. The photoresist ring according to claim 11, wherein a height of the lower layer ring is 2/3 of a height of the light-emitting mesa; or
the height of the lower layer ring is the same as a height of the light-emitting layer of the light-emitting mesa.

14. The photoresist ring according to claim 11, wherein:
the height of the lower layer ring ranges from 0.2 μm to 0.5 μm, and a height of the upper layer ring ranges from 1.3 μm to 1.7 μm; and/or
the thickness of the lower layer ring ranges from 1.9 μm to 2.4 μm, and the thickness of the upper layer ring ranges from 1.8 μm to 2.3 μm.

15. The photoresist ring according to claim 11, wherein:
the cross-sectional shape of the upper layer ring and/or the lower layer ring in a cross-section parallel to the upper surface of the light-emitting mesa is one of the following items: a triangle, a square, a rectangle, a circle, an ellipse, and an n-sided polygon, wherein n is an integer greater than 4; and/or
the longitudinal cross-sectional shape of the upper layer ring and/or the lower layer ring in a longitudinal cross-section perpendicular to the upper surface of the light-emitting mesa is one of the following items: a trapezoid, a triangle.

16. The photoresist ring according to claim 15, wherein the cross-sectional shape of the upper layer ring and the lower layer ring is square, and the square has rounded inner angles.

17. The photoresist ring according to claims claim 11, wherein:
the lower layer ring has a gradually decreasing thickness in the longitudinal cross-section perpendicular to the upper surface of the light-emitting mesa; and
the upper layer ring has a gradually decreasing thickness in the longitudinal cross-section perpendicular to the upper surface of the light-emitting mesa.

18. A micro-LED chip, comprising:
a light-emitting mesa, comprising:
a transparent conductive layer located on a side of the light-emitting mesa facing away from a light extraction side;
a light-emitting layer;
a first epitaxial layer located between the transparent conductive layer and the light-emitting layer; and
a second epitaxial layer located on a side of the light-emitting mesa facing the light extraction side, wherein the light-emitting layer is located between the first epitaxial layer and the second epitaxial layer, and an area of the second epitaxial layer is larger than an area of the first epitaxial layer;
a reflective mirror layer according to claim 1, surrounding the light-emitting mesa;
an insulating layer accommodating the light-emitting mesa and a plurality of through-hole contact portions;
a drive circuit comprising a metal layer on its surface, the drive circuit is provided with the plurality of through-hole contact portions, and the plurality of through-hole contact portions are electrically connected with the metal layer, and a micro-LED array area is bonded onto the drive circuit through a bottom conductive bonding layer, wherein the drive circuit also comprises a wiring stacked layer below the metal layer;
a first electrode electrically connected with the plurality of through-hole contact portions, wherein the wiring stacked layer leads out the first electrode;
a passivation layer covering at least a part of a side surface of the light-emitting mesa;
a top transparent conductive layer located on a surface of the passivation layer and in electrical contact with the second epitaxial layer; and
a second electrode located on a surface of the transparent conductive layer.

19. The micro-LED chip according to claim 18, wherein the second electrode is a circular reflective electrode arranged around the light-emitting mesa.

20. A method for forming a reflective mirror layer, comprising:
providing a light-emitting mesa;
forming a lower layer ring around the light-emitting mesa;
forming an upper layer ring on the lower layer ring, wherein at a connection portion between the upper layer ring and the lower layer ring, a thickness of the upper layer ring is greater than a thickness of the lower layer ring;
coating a reflective mirror layer on the light-emitting mesa, the upper layer ring, and the lower layer ring, wherein the reflective mirror layer forms, at the connection portion, an overhang layer detached from the lower layer ring, and the lower layer ring has a gap under the overhang layer that is not covered by the reflective mirror layer; and
removing the upper layer ring and the lower layer ring.
